(19) United States
(12) Patent Application Publication
(10) Pub. No.: US 2025/0255136 A1
(43) Pub. Date: Aug. 7, 2025

(54) DISPLAY APPARATUS

(71) Applicant: Samsung Display Co., LTD., Yongin-si (KR)

(72) Inventors: Soodong KIM, Yongin-si (KR); Junghwan YI, Yongin-si (KR); Raeyoung KIM, Yongin-si (KR)

(21) Appl. No.: 18/793,763

(22) Filed: Aug. 3, 2024

(30) Foreign Application Priority Data
Feb. 5, 2024 (KR) 10-2024-0017619

(51) Int. Cl. H10K 59/38; H10K 59/122; H10K 59/80

(52) U.S. Cl. CPC H10K 59/38; H10K 59/122; H10K 59/8791

(57) ABSTRACT

A display apparatus includes: a first light-emitting element to a third light-emitting element; a sub-pixel-defining layer in which a first opening to a third opening are defined, the first opening to the third opening overlapping the first light-emitting element to the third light-emitting element, respectively; an encapsulation layer disposed on the sub-pixel-defining layer; a functional layer disposed on the encapsulation layer and including a first quantum dot layer corresponding to the first light-emitting element and a second quantum dot layer corresponding to the second light-emitting element; and a color filter layer including a first color filter, a second color filter and a third color filter, where in a plan view, the second quantum dot layer includes a first portion overlapping the second opening, and a second portion extending from the first portion in a direction to the first opening, the second portion being adjacent to the first quantum dot layer.

This application claims priority to Korean Patent Application No. 10-2024-0017619, filed on Feb. 5, 2024, and all the benefits accruing therefrom under 35 U.S.C. § 119, the content of which in its entirety is herein incorporated by reference.

### BACKGROUND

### 1. Field

One or more embodiments relate to display apparatuses.

### 2. Description of the Related Art

With the rapid advancement of display fields in which various electrical signal information is visually represented, various display apparatuses with excellent characteristics such as reduced thickness, reduced weight, and lower power consumption have been introduced.

Display apparatuses may include liquid crystal display apparatuses that use light from a backlight without emitting light by itself, or light-emitting display apparatuses including display elements capable of emitting light. The light-emitting display apparatuses may include display elements including an emission layer.

### SUMMARY

One or more embodiments include a display apparatus with excellent color purity and excellent light efficiency. However, this aspect is only an example, and the scope of one or more embodiments is not limited thereby.

Additional aspects will be set forth in part in the description which follows and, in part, will be apparent from the description, or may be learned by practice of the presented embodiments of the disclosure.

According to one or more embodiments, a display apparatus includes: a first substrate; a first light-emitting element to a third light-emitting element disposed on the first substrate; a sub-pixel-defining layer in which a first opening to a third opening are defined, the first opening to the third opening overlapping the first light-emitting element to the third light-emitting element, respectively, in a plan view; an encapsulation layer disposed on the sub-pixel-defining layer and including at least one inorganic encapsulation layer and at least one organic encapsulation layer; a functional layer disposed on the encapsulation layer; the functional layer including a first quantum dot layer corresponding to the first light-emitting element and a second quantum dot layer corresponding to the second light-emitting element; and a color filter layer disposed in a direction of light output from the first light-emitting element to the third light-emitting element, the color filter layer including a first color filter corresponding to the first light-emitting element, a second color filter corresponding to the second light-emitting element, and a third color filter corresponding to the third light-emitting element, where, in the plan view, the second quantum dot layer includes a first portion overlapping the second opening, and a second portion, which extends from the first portion in a direction from the second opening to the first opening, and the second portion is adjacent to the first quantum dot layer.

The display apparatus may further include a first bank layer which is disposed between the sub-pixel-defining layer and the encapsulation layer and in which a first-1 bank opening to a first-3 bank opening overlapping the first light-emitting element to the third light-emitting element, respectively, in the plan view are defined, where the first bank layer may include a light-shielding material, and the second portion of the second quantum dot layer may overlap the first-1 bank opening in the plan view.

The display apparatus may further include: a second substrate arranged to face the first substrate, a low-refractive layer arranged to cover the color filter layer, the color filter layer being disposed on a surface of the second substrate, and a filler disposed between the low-refractive layer and the functional layer.

The second portion of the second quantum dot layer may overlap the first opening in the plan view.

The color filter layer may further include a fourth color filter, which overlaps the second portion of the second quantum dot layer in the plan view, the second color filter may overlap the first portion of the second quantum dot layer in the plan view, and the fourth color filter may include a composition different from a composition of the second color filter.

The second color filter may include a first filter portion overlapping the first portion of the second quantum dot layer and a second filter portion overlapping the second portion of the second quantum dot layer in the plan view, the second filter portion may include the same composition as the first filter portion, and a thickness of the second filter portion may be greater than a thickness of the first filter portion.

The first color filter may overlap the second portion of the second quantum dot layer in the plan view.

The display apparatus may further include a filter layer disposed entirely on the color filter layer.

The second portion of the second quantum dot layer may not overlap the first opening in the plan view.

At least two selected from the first color filter, the second color filter, and the third color filter may overlap each other in a certain portion and the certain portion may define a light-shielding portion, and the second portion of the second quantum dot layer may overlap the light-shielding portion in the plan view.

The first light-emitting element to the third light-emitting element may include an emission layer of a first color and an emission layer of a second color.

According to one or more embodiments, a display apparatus includes: a first substrate; a first light-emitting element to a third light-emitting element disposed on the first substrate; a sub-pixel-defining layer in which a first opening to a third opening are defined, the first opening to the third opening overlapping the first light-emitting element to the third light-emitting element, respectively, in a plan view; a first bank layer which is disposed on the sub-pixel-defining layer and in which a first-1 bank opening to a first-3 bank opening overlapping the first light-emitting element to the third light-emitting element, respectively, in the plan view, are defined; an encapsulation layer disposed on the first bank layer and including at least one inorganic encapsulation layer and at least one organic encapsulation layer; a functional layer disposed on the encapsulation layer, the functional layer including a first quantum dot layer corresponding to the first light-emitting element and a second quantum dot layer corresponding to the second light-emitting element; and a color filter layer disposed in a direction of light output from the first light-emitting element to the third light-emitting element, the color filter layer including a first color filter corresponding to the first light-emitting element, a second color filter corresponding to the second light-emitting element, and a third color filter corresponding to the third light-emitting element, where the second quantum dot layer overlaps the first-1 bank opening in the plan view.

The first bank layer may include a light-shielding material.

In the plan view, the second quantum dot layer may include a first portion overlapping the second opening, and a second portion, which extends from the first portion in a direction from the second opening to the first opening, and the second portion may be adjacent to the first quantum dot layer.

The second portion of the second quantum dot layer may overlap the first opening in the plan view.

The color filter layer may further include a fourth color filter, which overlaps the second portion of the second quantum dot layer in the plan view, the second color filter may overlap the first portion of the second quantum dot layer in the plan view, and the fourth color filter may include a composition different from a composition of the second color filter.

The second color filter may include a first filter portion overlapping the first portion of the second quantum dot layer and a second filter portion overlapping the second portion of the second quantum dot layer in the plan view, the second filter portion may include the same composition as the first filter portion, and a thickness of the second filter portion may be greater than a thickness of the first filter portion.

The first color filter may overlap the second portion of the second quantum dot layer in the plan view.

The second portion of the second quantum dot layer may not overlap the first opening in the plan view.

At least two selected from the first color filter, the second color filter, and the third color filter may overlap each other in a certain portion and the certain portion may define a light-shielding portion, and the second portion of the second quantum dot layer may overlap the light-shielding portion in the plan view.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a cross-sectional view schematically illustrating a sub-pixel of a display apparatus according to an embodiment;

FIG. 3 shows each of optical layers of a functional layer of FIG. 2;

FIGS. 4A to 4E are cross-sectional views illustrating a structure of a light-emitting element according to an embodiment;

FIG. 5 is an equivalent circuit diagram illustrating a light-emitting element included in a display apparatus and a sub-pixel circuit electrically connected to the light-emitting element, according to an embodiment;

FIG. 6 is a cross-sectional view schematically illustrating a display apparatus according to an embodiment;

FIG. 7 is a cross-sectional view schematically illustrating a display apparatus according to another embodiment;

FIGS. 8A and 8B are plan views schematically illustrating a portion of a display apparatus according to an embodiment;

FIG. 9 is a cross-sectional view schematically illustrating a portion of a display apparatus according to an embodiment;

FIG. 10 is a graph showing a light transmittance spectra of a first filter portion and a second filter portion of the second color filter of FIG. 9;

FIG. 11 is a cross-sectional view schematically illustrating a portion of a display apparatus according to an embodiment;

FIG. 12 is a graph showing a light transmittance spectrum of a second color filter and a fourth color filter of FIG. 11;

FIGS. 13A and 13B are plan views schematically illustrating a portion of a display apparatus according to an embodiment;

FIG. 14 is a cross-sectional view schematically illustrating a portion of a display apparatus according to an embodiment;

FIG. 15 is a graph showing a light transmittance spectra of a first color filter of FIG. 14 and a first color filter of FIG. 9;

FIG. 16 is a cross-sectional view schematically illustrating a portion of a display apparatus according to an embodiment;

FIGS. 17A and 17B are plan views schematically illustrating a portion of a display apparatus according to an embodiment;

FIG. 18 is a cross-sectional view schematically illustrating a portion of a display apparatus according to an embodiment; and

FIG. 19 is a graph schematically showing a color space of a display apparatus and a digital cinema initiatives (DCI) color space, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are shown. This disclosure may, however, be embodied in many different forms and should not be construed as limited to the embodiments set forth herein.

Hereinafter, embodiments will be described with reference to the accompanying drawings, wherein like reference numerals refer to like elements throughout and a repeated description thereof is omitted.

It will be understood that although terms such as “first” and “second” may be used herein to describe various elements, these elements should not be limited by these terms and these terms are only used to distinguish one element from another element.

In an embodiment below, an expression used in the singular encompasses the expression of the plural, unless it has a clearly different meaning in the context.

In an embodiment below, it will be further understood that the terms “comprises” and/or “comprising” used herein specify the presence of stated features or elements, but do not preclude the presence or addition of one or more other features or elements.

In the following embodiments, when a part of a film, area, element, or the like is disposed over or on another part, it refers not only to a case where the part is directly on top of the other part, but also a case where another film, area, element, or the like is located therebetween.

In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

When an embodiment can be implemented differently, a specific process sequence may be performed differently from the described sequence. For example, two processes described in succession may be performed substantially at the same time, or may be performed in an order opposite to the described sequence.

Herein, “A and/or B” indicates A, B, or A and B. In addition, “at least one of A or B” indicates A, B, or A and B.

In the following embodiments, when films, areas, elements, or the like are described to be connected, it includes a case where the films, the areas, the elements, or the like are directly connected, or/and a case where the films, the areas, the elements, or the like are indirectly connected with other films, areas, or elements therebetween. For example, herein, when it is described that films, areas, elements, or the like are electrically connected, it indicates a case where the films, areas, elements, or the like are directly electrically connected, or/and a case where the films, areas, the elements, or the like are indirectly electrically connected with other films, areas, or elements therebetween.

An x-axis, a y-axis, and a z-axis are not limited to the three axes in the Cartesian coordinate system, but can be interpreted in a broad sense including the same. For example, the x-axis, the y-axis, and the z-axis may be orthogonal to each other, but may also refer to directions that are not orthogonal to each other.

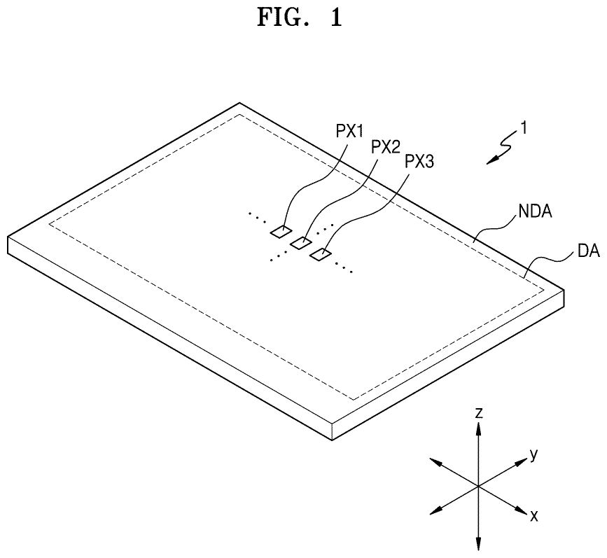

FIG. 1 is a perspective view schematically illustrating a display apparatus 1 according to an embodiment.

Referring to FIG. 1, the display apparatus 1 may include a display area DA in which an image is implemented, and a non-display area NDA in which no image is implemented. The display apparatus 1 may provide an image through an array of a plurality of sub-pixels that are two-dimensionally disposed on an x-y plane. Each of the sub-pixels may emit light of different colors and may be, for example, one of a red sub-pixel, a green sub-pixel, and a blue sub-pixel.

In an embodiment, the plurality of sub-pixels may include a first sub-pixel PX1, a second sub-pixel PX2, and a third sub-pixel PX3, and hereinbelow, for convenience of description, a case is described in which the first sub-pixel PX1 is a red-subpixel, the second sub-pixel PX2 is a green sub-pixel, and the third sub-pixel PX3 is a blue sub-pixel.

The first sub-pixel PX1, the second sub-pixel PX2, and the third sub-pixel PX3 are areas in which red light, green light, and blue light are emitted, respectively, and the display apparatus 1 may provide an image by using light emitted from the sub-pixels.

The non-display area NDA does not provide an image and may surround the display area DA entirely. A driver or a main voltage line for providing electrical signals or power to sub-pixel circuits may be arranged in the non-display area NDA. The non-display area NDA may include a pad to which an electronic element or a printed circuit board may be electrically connected.

The display area DA may have a polygonal shape, including a rectangle, as shown in FIG. 1. For example, the display area DA may have a rectangular shape of which a horizontal length is greater than a vertical length, a rectangular shape of which the horizontal length is less than the vertical length, or a square shape. In another embodiment, the display area DA may be circular, elliptical, or polygonal such as a triangle or a pentagon. In addition, in FIG. 1, a flat panel display apparatus is shown as the display apparatus 1. However, the display apparatus 1 may be implemented in various forms such as flexible, foldable, or rollable display apparatuses.

In an embodiment, the display apparatus 1 may be an organic light-emitting display apparatus. In another embodiment, the display apparatus 1 may be an inorganic light-emitting display apparatus or a quantum dot light-emitting display apparatus. For example, an emission layer of a display element included in a display apparatus may include an organic material, an inorganic material, quantum dots, both an organic material and quantum dots, both an inorganic material and quantum dots, or all of an organic material, an inorganic material, and quantum dots. Hereinbelow, for convenience of description, a case in which the display apparatus 1 is an organic light-emitting display apparatus is mainly described in detail.

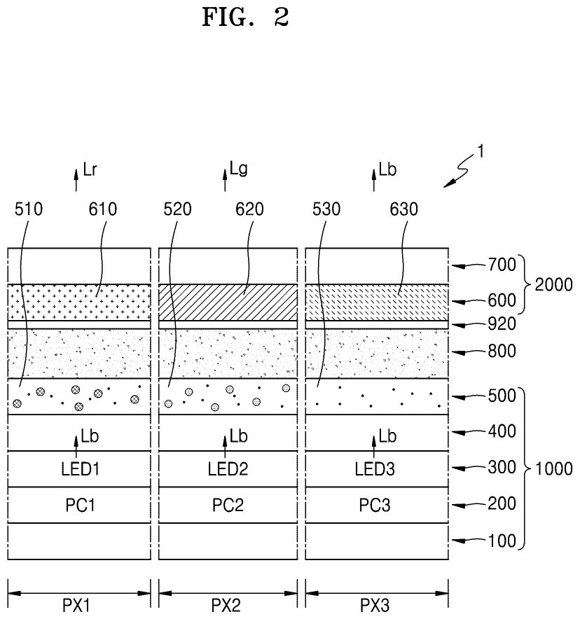

FIG. 2 is a cross-sectional view schematically illustrating a sub-pixel of the display apparatus 1 according to an embodiment.

Referring to FIG. 2, the display apparatus 1 may include a circuit layer 200 on a first substrate 100. The circuit layer 200 may include a first sub-pixel circuit to a third sub-pixel circuit PC1, PC2, and PC3, and each of the first sub-pixel circuit to the third sub-pixel circuit PC1, PC2, and PC3 may include a thin-film transistor and/or a capacitor. The first sub-pixel circuit to the third sub-pixel circuit PC1, PC2, and PC3 may be electrically connected to a first light-emitting element to a third light-emitting element LED1, LED2, and LED3 of a light-emitting element layer 300.

The first light-emitting element to the third light-emitting element LED1, LED2, and LED3 may include an organic light-emitting diode including an organic material. In another embodiment, the first light-emitting element to the third light-emitting element LED1, LED2, and LED3 may include an inorganic light-emitting diode including an inorganic material. The inorganic light-emitting diode may include a PN junction diode including materials based on an inorganic material semiconductor. When a voltage is applied to the PN junction diode in a forward direction, holes and electrons may be injected, and energy generated from a recombination of the holes and the electrons may be converted into light energy to emit light of a certain color. The inorganic light-emitting diode described above may have a width of several to hundreds of micrometer or several to hundreds of nanometers. In some embodiments, the first light-emitting element to the third light-emitting element LED1, LED2, and LED3 may be light-emitting diodes including quantum dots. As described above, the emission layers of the first light-emitting element to the third light-emitting element LED1, LED2, and LED3 may include an organic material, an inorganic material, quantum dots, both an organic material and quantum dots, or an inorganic material and quantum dots.

The first light-emitting element to the third light-emitting element LED1, LED2, and LED3 may emit light of the same color. For example, light emitted from the first light-emitting element to the third light-emitting element LED1, LED2, and LED3 (e.g., blue light Lb) may pass through a functional layer 500 via an encapsulation layer 400 that is on the light-emitting element layer 300. However, one or more embodiments are not limited thereto. In another embodiment, the first light-emitting element to the third light-emitting element LED1, LED2, and LED3 may emit light of different colors.

The functional layer 500 may include optical layers that transmit the light emitted from the light-emitting element layer 300 (e.g., blue light Lb) with or without conversion of a color of the light. For example, the functional layer 500 may include quantum dot layers that convert light emitted from the light-emitting element layer 300 (e.g., blue light Lb) into light of another color, and a transmissive layer that transmits light emitted from the light-emitting element layer 300 (e.g., blue light Lb) without color conversion. The functional layer 500 may include a first quantum dot layer 510 corresponding to the first sub-pixel PX1, a second quantum dot layer 520 corresponding to the second sub-pixel PX2, and a light-transmitting layer 530 corresponding to the third sub-pixel PX3. The first quantum dot layer 510 may convert blue light Lb into red light Lr, and the second quantum dot layer 520 may convert blue light Lb into green light Lg. The light-transmitting layer 530 may transmit the blue light Lb without conversion.

A color filter layer 600 may include first to third color filters 610, 620, and 630 of different colors. In an embodiment, the first color filter 610 may be a red color filter, the second color filter 620 may be a green color filter, and the third color filter 630 may be a blue color filter.

Light that is color-converted in the functional layer 500 or transmits the functional layer 500 may achieve improved color purity while passing through the first to third color filters 610, 620, and 630. In addition, the color filter layer 600 may prevent or minimize external light (e.g., light incident toward the display apparatus 1 from the outside of the display apparatus 1) from being reflected and seen by a user.

In an embodiment, the display apparatus 1 may include the first substrate 100 and a second substrate 700, which are arranged to face each other. The second substrate 700 may include glass or a light-transmitting organic material. For example, the second substrate 700 may include a light-transmitting organic material such as acryl-based resin. The display apparatus 1 may include a light-emitting panel 1000 and a color filter panel 2000, which are arranged to be spaced apart from each other with a filler 800 therebetween. The light-emitting panel 1000 may include the circuit layer 200, the light-emitting element layer 300, the encapsulation layer 400, and the functional layer 500 on the first substrate 100. In other words, the functional layer 500 may be formed over the first substrate 100 rather than the second substrate 700. In this case, the functional layer 500 may be disposed on the encapsulation layer 400 to be in direct contact with the encapsulation layer 400. Through this configuration, a distance between the first light-emitting element to the third light-emitting element LED1, LED2, and LED3 and the functional layer 500 may be reduced, and light lost during a path may be minimized, thereby improving light efficiency.

In an embodiment, the color filter panel 2000 may include the color filter layer 600 on a surface of the second substrate 700 facing the first substrate 100. A low-refractive layer 920 may be further disposed on the color filter layer 600. The color filter layer 600 may be arranged to face the functional layer 500 with the filler 800 therebetween. The filler 800 may fill in a space between the light-emitting panel 1000 and the color filter panel 2000 after the light-emitting panel 1000 and the color filter panel 2000 are bonded to each other. The filler 800 may include a light-transmitting material such as acrylic resin or epoxy resin.

In another embodiment, after the functional layer 500 and the color filter layer 600 are sequentially formed on the encapsulation layer 400, a cover layer (not shown) may be directly coated and cured on the color filter layer 600. In some embodiments, the cover layer may include a light-transmitting organic material. Other optical films such as an anti-reflection (AR) film may be further disposed on the cover layer.

The display apparatus 1 having the structure described above may include an electronic apparatus capable of displaying moving images or still images, such as a television, a billboard, a cinema screen, a monitor, a tablet personal computer (PC), or a laptop.

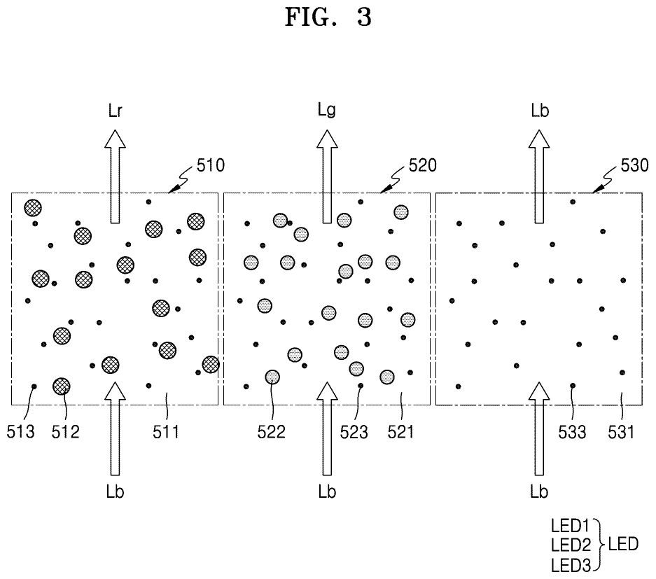

FIG. 3 a diagram illustrating each of optical layers of the functional layer 500 of FIG. 2.

Referring to FIG. 3, the first quantum dot layer 510 may convert blue light Lb that is incident thereon into red light Lr. The first quantum dot layer 510 may include a first photosensitive polymer 511 and may include a first quantum dot 512 and first scattering particles 513 that are dispersed in the first photosensitive polymer 511.

The first quantum dot 512 may be excited by the blue light Lb and may emit red light Lr having a longer wavelength than the blue light Lb. The first photosensitive polymer 511 may be an organic material with light transparency.

The first scattering particles 513 may excite the first quantum dots 512 by scattering blue light Lb that has not been absorbed by the first quantum dot 512, thereby improving color conversion efficiency. For example, the first scattering particles 513 may be titanium oxide (TiO₂) or metal particles. The first quantum dot 512 may be selected from among group II-VI compounds, group III-V compounds, group IV-VI compounds, group IV elements, group IV compounds, and a combination thereof.

The group II-VI compounds may be selected from the group consisting of binary compounds, which are selected from the group consisting of CdSe, CdTe, ZnS, ZnSe, ZnTe, ZnO, HgS, HgSe, HgTe, MgSe, MgS, and a mixture thereof, ternary compounds, which are selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and quaternary compounds, which are selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a compound thereof.

The group III-VI compounds may include binary compounds, such as In₂S₃ or In₂Se₃, ternary compounds, such as InGaS₃ or InGaSe₃, or any combinations thereof.

The group III-V compounds may be selected from the group consisting of binary compounds, which are selected from the group consisting of GaN, GaP, GaAs, GaSb, AlN, AlP, AlAs, AlSb, InN, InP, InAs, InSb, and a mixture thereof, ternary compounds, which are selected from the group consisting of GaNP, GaNAs, GaNSb, GaPAs, GaPSb, AlNP, AlNAs, AlNSb, AlPAS, AlPSb, InNP, InAlP, InNAs, InNSb, InPAs, InPSb, GaAlNP, and a mixture thereof, and quaternary compounds, which are selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSB, and a mixture thereof. The group III-V semiconductor compounds may further include a group II metal (e.g., InZnP or the like).

The group IV-VI compounds may be selected from the group consisting of binary compounds, which are selected from the group consisting of SnS, SnSe, SnTe, PbS, PbSe, PbTe, and a mixture thereof, ternary compounds, which are selected from the group consisting of SnSeS, SnSeTe, SnSTe, PbSeS, PbSeTe, PbSTe, SnPbS, SnPbSe, SnPbTe, and a mixture thereof, and quaternary compounds, which are selected from the group consisting of SnPbSSe, SnPbSeTe, SnPbSTe, and a mixture thereof. The group IV elements may be selected from the group consisting of silicon (Si), germanium (Ge), and a mixture thereof. The group IV compounds may be binary compounds selected from the group consisting of silicon carbide (SiC), silicon germanium (SiGe), and a mixture thereof.

The second quantum dot layer 520 may convert the blue light Lb incident thereon into green light Lg. The second quantum dot layer 520 may include a second photosensitive polymer 521 and may include second quantum dots 522 and second scattering particles 523 that are dispersed in the second photosensitive polymer 521.

The second quantum dots 522 may be excited by the blue light Lb and may emit green light Lg having a longer wavelength than the blue light Lb. The second photosensitive polymer 521 may be an organic material with light transparency.

The second scattering particles 523 may excite the second quantum dots 522 by scattering blue light Lb that has not been absorbed by the second quantum dot 522, thereby improving color conversion efficiency. For example, the second scattering particles 523 may be TiO₂ or metal particles. The second quantum dots 522 may be selected from among group II-VI compounds, group III-V compounds, group IV-VI compounds, group IV elements, group IV compounds, and a combination thereof.

In some embodiments, the first quantum dot 512 and the second quantum dots 522 may be the same material. In this case, a size of the first quantum dot 512 may be greater than a size of the second quantum dots 522.

The light-transmitting layer 530 may transmit the blue light Lb incident on the light-transmitting layer 530 without converting the blue light Lb. The light-transmitting layer 530 may include a third photosensitive polymer 531 in which third scattering particles 533 are dispersed. For example, the third photosensitive polymer 531 may be an organic material with light transparency, such as silicon resin or epoxy resin, and may be the same material as the first and second photosensitive polymers 511 and 521. The third scattering particles 533 may scatter and emit the blue light Lb and may be the same material as the first and second scattering particles 513 and 523.

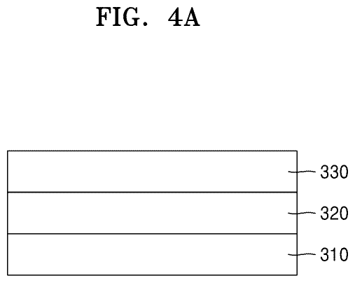

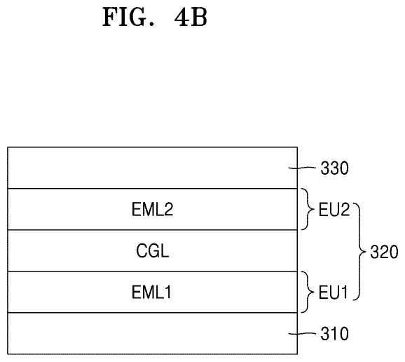

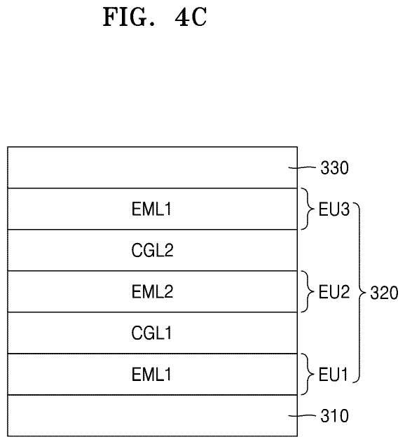

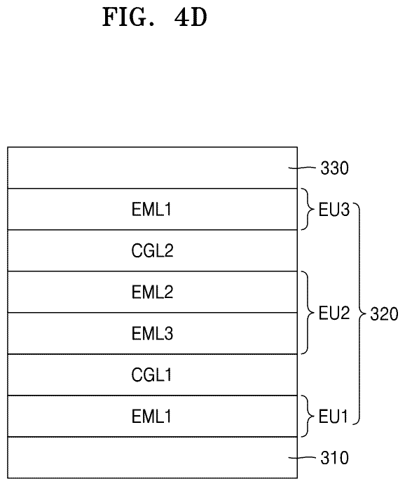

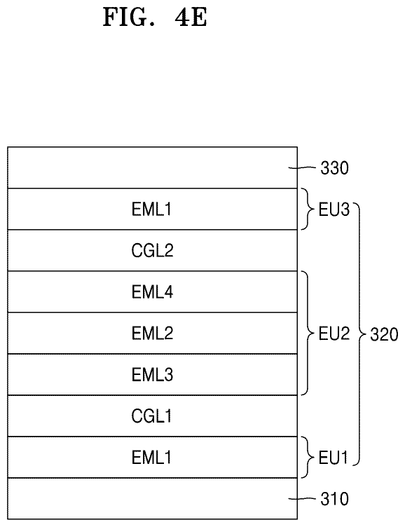

FIGS. 4A to 4E are cross-sectional views illustrating a structure of a light-emitting element LED that may be included in the light-emitting element layer 300 of FIG. 2.

Referring to FIG. 4A, the light-emitting element LED according to an embodiment may include a sub-pixel electrode 310, an opposite electrode 330, and an intermediate layer 320 that is between the sub-pixel electrode 310 (e.g., an anode) and the opposite electrode 330 (e.g., a cathode). In an embodiment, the light-emitting element LED may be an organic light-emitting element.

The sub-pixel electrode 310 may include a conductive oxide that transmits light, such as indium tin oxide (ITO), indium zinc oxide (IZO), zinc oxide (ZnO), indium oxide (In₂O₃), indium gallium oxide (IGO), or aluminum zinc oxide (AZO). The sub-pixel electrode 310 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. For example, the sub-pixel electrode 310 may have a three-layer structure of ITO/Ag/ITO.

The opposite electrode 330 may be disposed on the intermediate layer 320. The opposite electrode 330 may include metals with a low work function, alloys, electrically conductive compounds, or any combinations thereof. For example, the opposite electrode 330 may include lithium (Li), Ag, Mg, AI, AI-Li, calcium (Ca), magnesium-indium (Mg—In), Mg—Ag, ytterbium (Yb), Ag—Yb, ITO, IZO, or any combinations thereof. The opposite electrode 330 may be a transmissive electrode, a semi-transmissive electrode, or a reflective electrode.

The intermediate layer 320 may include a polymer or low-molecular weight organic material that emits light of a certain color. In addition to various organic materials, the intermediate layer 320 may further include metal-containing compounds such as an organic metal compound, or an inorganic material such as quantum dots.

In an embodiment, the intermediate layer 320 may include one emission layer and may include a first functional layer and a second functional layer that are under and over the emission layer, respectively. The first functional layer may include, for example, a hole transport layer (HTL) or both an HTL and a hole injection layer (HIL). The second functional layer, which is disposed over the emission layer, is optional. The second functional layer may include an electron transport layer (ETL) and/or an electron injection layer (EIL).

Referring to FIGS. 4B to 4E, in an embodiment, the intermediate layer 320 may include at least two emitting units that are sequentially stacked between the sub-pixel electrode 310 and the opposite electrode 330, and a charge generation layer CGL arranged between the at least two emitting units. The emitting units may emit light in different wavelength bands. When the intermediate layer 320 includes an emitting unit and the charge generation layer CGL, the light-emitting element LED may be a tandem light-emitting element. The light-emitting element LED may have improved color purity and improved emission efficiency due to the stacked structure of a plurality of emitting units thereof.

A single emitting unit may include an emission layer and may include a first functional layer and a second functional layer that are under and over the emission layer, respectively. The charge generation layer CGL may include a negative charge generation layer and a positive charge generation layer. Due to the negative charge generation layer and the positive charge generation layer, emission efficiency of the light-emitting element LED that is a tandem light-emitting element having a plurality of emission layers may be further improved.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In an embodiment, as shown in FIG. 4B, the light-emitting element LED may include a first emitting unit EU1 and a second emitting unit EU2 that are sequentially stacked, where the first emitting unit EU1 includes a first emission layer EML1, and the second emitting unit EU2 includes a second emission layer EML2. The charge generation layer CGL may be provided between the first emitting unit EU1 and the second emitting unit EU2. For example, the light-emitting element LED may include the sub-pixel electrode 310, the first emission layer EML1, the charge generation layer CGL, the second emission layer EML2, and the opposite electrode 330, which are sequentially stacked. The first functional layer and the second functional layer may be included under and over the first emission layer EML1, respectively. The first functional layer and the second functional layer may be included under and over the second emission layer EML2, respectively.

In an embodiment, as shown in FIG. 4C, the light-emitting element LED may include a first emitting unit EU1, a second emitting unit EU2, and a third emitting unit EU3, where the first emitting unit EU1 and the third emitting unit EU3 include the first emission layer EML1, and the second emitting unit EU2 includes the second emission layer EML2. A first charge generation layer CGL1 may be provided between the first emitting unit EU1 and the second emitting unit EU2, and a second charge generation layer CGL2 may be provided between the second emitting unit EU2 and the third emitting unit EU3. For example, the light-emitting element LED may include the sub-pixel electrode 310, the first emission layer EML1, the first charge generation layer CGL1, the second emission layer EML2, and the second charge generation layer CGL2, the first emission layer EML1, and the opposite electrode 330, which are sequentially stacked. The first functional layer and the second functional layer may be included under and over the first emission layer EML1, respectively. The first functional layer and the second functional layer may be included under and over the second emission layer EML2, respectively.

In an embodiment, in the light-emitting element LED, in addition to the second emission layer EML2, the second emitting unit EU2 may further include a third emission layer EML3 and/or a fourth emission layer EML4 that are in direct contact with a lower portion and/or upper portion of the second emission layer EML2. Here, “being in direct contact” may denote that no other layers are arranged between the second emission layer EML2 and the third emission layer EML3 and/or between the second emission layer EML2 and the fourth emission layer EML4.

For example, as shown in FIG. 4D, the light-emitting element LED may include the sub-pixel electrode 310, the first emission layer EML1, the first charge generation layer CGL1, the third emission layer EML3, the second emission layer EML2, the second charge generation layer CGL2, the first emission layer EML1, and the opposite electrode 330, which are sequentially stacked. Alternatively, as shown in FIG. 4E, the light-emitting element LED may include the sub-pixel electrode 310, the first emission layer EML1, the first charge generation layer CGL1, the third emission layer EML3, the second emission layer EML2, the fourth emission layer EML4, the second charge generation layer CGL2, the first emission layer EML1, and the opposite electrode 330, which are sequentially stacked.

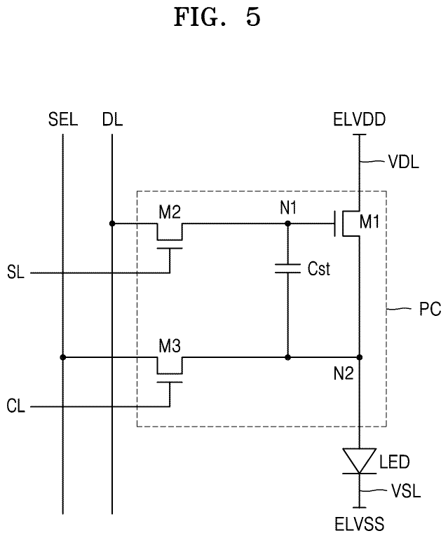

FIG. 5 is an equivalent circuit diagram illustrating a light-emitting element included in a display apparatus and a sub-pixel circuit electrically connected to the light-emitting element, according to an embodiment.

Referring to FIG. 5, a sub-pixel electrode (e.g., an anode) of the light-emitting element LED may be electrically connected to a sub-pixel electrode PC, and an opposite electrode (e.g., a cathode) of the light-emitting element LED may be connected to a common voltage line VSL, which provides a common power voltage ELVSS. The light-emitting element LED may emit light with a luminance corresponding to an amount of current supplied from the sub-pixel electrode PC.

The light-emitting element LED of FIG. 5 may correspond to each of the first light-emitting element to the third light-emitting element LED1, LED2, and LED3 shown in FIG. 2, and the sub-pixel electrode PC of FIG. 5 may correspond to each of the first sub-pixel circuit to the third sub-pixel circuit PC1, PC2, and PC3 shown in FIG. 2.

In response to a data signal, the sub-pixel electrode PC may control the amount of current that flows from a driving power voltage ELVDD to the common power voltage ELVSS via the light-emitting element LED. The sub-pixel electrode PC may include a first transistor M1, a second transistor M2, a third transistor M3, and a storage capacitor Cst.

Each of the first transistor M1, the second transistor M2, and the third transistor M3 may be an oxide semiconductor thin-film transistor including a semiconductor layer, the semiconductor layer including an oxide semiconductor, or may be a silicon semiconductor thin-film transistor including a semiconductor layer, the semiconductor layer including polysilicon. A transistor includes a first electrode and a second electrode, and depending on a type, the first electrode may be one of a source electrode and a drain electrode, and the second electrode may be the other one of the source electrode and the drain electrode.

The first transistor M1 may be a driving transistor. A first electrode of the first transistor M1 may be electrically connected to a driving voltage line VDL configured to supply the driving power voltage ELVDD, and a second electrode of the first transistor M1 may be electrically connected to the sub-pixel electrode of the light-emitting element LED. A gate electrode of the first transistor M1 may be electrically connected to a first node N1. In response to a voltage at the first node N1, the first transistor M1 may control an amount of current that flows from the driving power voltage ELVDD to the light-emitting element LED.

The second transistor M2 may be a switching transistor. A first electrode of the second transistor M2 may be electrically connected to a data line DL, and a second electrode of the second transistor M2 may be electrically connected to the first node N1. A gate electrode of the second transistor M2 may be electrically connected to a scan line SL. The second transistor M2 may be turned on when receiving a scan signal via the scan line SL, and may electrically connect the data line DL to the first node N1.

The third transistor M3 may be an initialization transistor and/or a sensing transistor. A first electrode of the third transistor M3 may be electrically connected to a second node N2, and a second electrode of the third transistor M3 may be connected to a sensing line SEL. A gate electrode of the third transistor M3 may be electrically connected to a control line CL.

The third transistor M3 may be turned on when receiving a control signal via the control line CL, and may electrically connect the sensing line SEL to the second node N2. In some embodiments, the third transistor M3 may be turned on in response to a signal received via the control line CL, and may transfer an initialization voltage from the sensing line SEL to the light-emitting element LED and initialize the sub-pixel electrode. In some embodiments, the third transistor M3 may be turned on when a control signal is received via the control line CL, and may sense characteristic information of the light-emitting element LED. The third transistor M3 may have both a function as the initialization transistor described above and a function as the sensing transistor, or may have at least one. In some embodiments, when the third transistor M3 has the function as the initialization transistor, the sensing line SEL may be called an initialization voltage line. The initialization operation and the sensing operation of the third transistor M3 may be performed individually or simultaneously.

The storage capacitor Cst may be connected between the first node N1 and the second node N2. For example, a first capacitor electrode of the storage capacitor Cst may be electrically connected to the gate electrode of the first transistor M1, and a second capacitor electrode of the storage capacitor Cst may be electrically connected to the sub-pixel electrode of the light-emitting element LED.

In FIG. 5, the first transistor M1, the second transistor M2, and the third transistor M3 are n-type metal-oxide-semiconductor field-effect transistors (MOSFETs; NMOSs). However, in another embodiment, at least one of the first transistor M1, the second transistor M2, and the third transistor M3 may be provided as a p-type MOSFET (PMOS).

In FIG. 5, three transistors are shown. However, in another embodiment, the sub-pixel electrode PC may include four or more transistors.

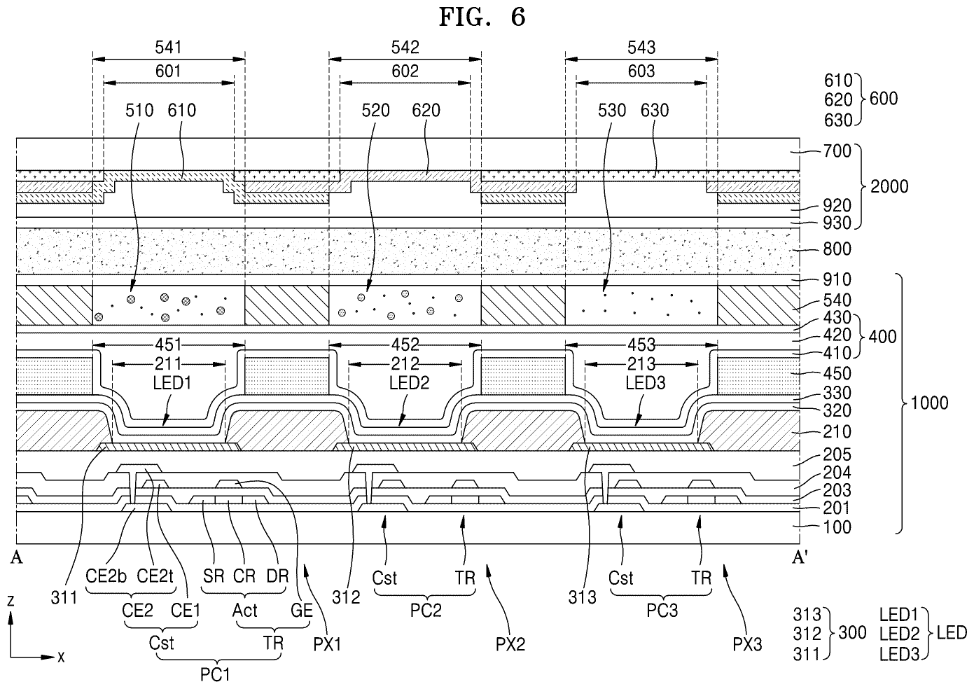

FIG. 6 is a cross-sectional view schematically illustrating a display apparatus according to an embodiment.

Referring to FIG. 6, first to third sub-pixel circuits PC1, PC2, and PC3 may be disposed on the first substrate 100. The first substrate 100 may be a glass substrate containing silicon dioxide (SiO₂) as a main component. For example, the glass substrate may be a glass substrate with a thickness of about 500 μm or an ultra-thin glass substrate with a thickness of about 30 μm. In another embodiment, the first substrate 100 may include polymer resin. The first substrate 100 including the polymer resin may have flexible, foldable, rollable, or bendable properties. In another embodiment, the first substrate 100 may have a multi-layer structure including a layer and an inorganic layer, the layer including the polymer resin.

As described above with reference to FIG. 5, each of the first to third sub-pixel circuits PC1, PC2, and PC3 may include a first transistor, a second transistor, a third transistor, and a storage capacitor. Regarding this, FIG. 6 shows a transistor TR and a storage capacitor Cst corresponding to any one of a first transistor, a second transistor, and a third transistor.

In an embodiment, the storage capacitor Cst may include a first capacitor electrode CE1 and a second capacitor electrode CE2, and the second capacitor electrode CE2 may include a first sub-capacitor electrode CE2b and a second sub-capacitor electrode CE2t, which are disposed under and over the first capacitor electrode CE1, respectively, with the first capacitor electrode CE1 therebetween.

The first sub-capacitor electrode CE2b may be disposed on the first substrate 100. For example, the first sub-capacitor electrode CE2b may be in direct contact with an upper surface of the first substrate 100. The first sub-capacitor electrode CE2b may include metals with conductivity, such as Al, Pt, Pd, Ag, Mg, Au, Ni, Nd, Ir, Cr, Ni, Ca, molybdenum (Mo), titanium (Ti), tungsten (W), and/or copper (Cu). Although not shown, the driving voltage line, the common voltage line, and/or the data line described with reference to FIG. 5 may be formed together in the same process as a process in which the first sub-capacitor electrode CE2b is formed.

A buffer layer 201 may be disposed on the second sub-capacitor electrode CE2t and may include an inorganic insulating material. The buffer layer 201 may include an inorganic insulating material such as silicon nitride, silicon oxide, and/or silicon oxynitride, and may include a single-layer or multi-layer structure including the materials described above.

A semiconductor layer Act may be disposed on the buffer layer 201. The semiconductor layer Act may include an oxide-based semiconductor material such as indium gallium zinc oxide (IGZO), amorphous silicon, polycrystalline silicon, or an organic semiconductor material.

A gate insulating layer 203 may be disposed on the semiconductor layer Act. The gate insulating layer 203 may include an inorganic insulating material such as silicon nitride, silicon oxide, and/or silicon oxynitride, and may include a single-layer or multi-layer structure including the materials described above.

A gate electrode GE may be disposed on the gate insulating layer 203 and may overlap a portion of the semiconductor layer Act. The gate electrode GE may overlap a channel region CR of the semiconductor layer Act in a plan view, and the semiconductor layer Act may include the channel region CR, a source region SR, and a drain region DR, and the source region SR and the drain region DR may be arranged at opposite sides of the channel region CR, respectively.

The first capacitor electrode CE1 may be arranged on the same layer as a layer on which the gate electrode GE is arranged, and may include the same material. The first capacitor electrode CE1 and the gate electrode GE may be formed through the same process. The first capacitor electrode CE1 and the gate electrode GE may include metals with conductivity, such as Al, Pt, Pd, Ag, Mg, Au, Ni, Nd, Ir, Cr, Ni, Ca, Mo, Ti, W, and/or Cu. According to an embodiment, the first capacitor electrode CE1 and the gate electrode GE may have a layered structure of Mo/Al/Mo. In another embodiment, the first capacitor electrode CE1 and the gate electrode GE may include a titanium nitride (TiNₓ) layer, an Al layer, and/or a Ti layer.

An interlayer-insulating layer 204 may be disposed on the first capacitor electrode CE1 and the gate electrode GE. The interlayer-insulating layer 204 may include an inorganic insulating material such as silicon nitride, silicon oxide, and/or silicon oxynitride, and may include a single-layer or multi-layer structure including the materials described above.

The second sub-capacitor electrode CE2t may be disposed on the interlayer-insulating layer 204. The second sub-capacitor electrode CE2t may be electrically connected to the first sub-capacitor electrode CE2b through a contact hole that passes through an insulating layer, the insulating layer being located between the second sub-capacitor electrode CE2t and the first sub-capacitor electrode CE2b. For example, the second sub-capacitor electrode CE2t may be connected to the first sub-capacitor electrode CE2b through a contact hole that passes through the buffer layer 201, the gate insulating layer 203, and the interlayer-insulating layer 204. The second sub-capacitor electrode CE2t may include, for example, a Ti layer, an Al layer, and/or a Cu layer. According to an embodiment, the second sub-capacitor electrode CE2t may have a layered structure of Ti/Al/Ti.

A via insulating layer 205 may be disposed on the first sub-pixel circuit to the third sub-pixel circuit PC1, PC2, and PC3. The via insulating layer 205 may include an inorganic insulating material and/or an organic insulating material. For example, the via insulating layer 205 may include an organic insulating material such as acryl, benzocyclobutene (BCB), polyimide, or hexamethyldisiloxane (HMDSO). The via insulating layer 205 may be provided as one or more layers.

Each of the first sub-pixel circuit to the third sub-pixel circuit PC1, PC2, and PC3 disposed on the first substrate 100 may include the transistor TR and the storage capacitor Cst having a structure as described above, and may be electrically connected to the sub-pixel electrode 310 of a corresponding light-emitting element.

A first light-emitting element LED1 including a first sub-pixel electrode 311, the opposite electrode 330, and the intermediate layer 320 therebetween may be positioned in the first sub-pixel PX1, the intermediate layer 320 including an emission layer. A second emission layer LED2, which is an organic light-emitting diode including a second sub-pixel electrode 312, the opposite electrode 330, and the intermediate layer 320 therebetween, may be positioned in the second sub-pixel PX2, the intermediate layer 320 including an emission layer. In addition, a third light-emitting element LED3, which is an organic light-emitting element having a third sub-pixel electrode 313, the opposite electrode 330, and the intermediate layer 320 therebetween, may be positioned in the third sub-pixel PX3, the intermediate layer 320 including an emission layer. The description of the first sub-pixel electrode 311 provided above may be applicable to the second sub-pixel electrode 312 and the third sub-pixel electrode 313.

The intermediate layer 320 may be positioned not only on the first sub-pixel electrode 311 of the first sub-pixel PX1, but also on the second sub-pixel electrode 312 of the second sub-pixel PX2 and the third sub-pixel electrode 313 of the third sub-pixel PX3. The intermediate layer 320 may have an integral shape across the first sub-pixel electrode 311, the second sub-pixel electrode 312, and the third sub-pixel electrode 313. The intermediate layer 320 may be patterned and positioned on the first sub-pixel electrode 311, the second sub-pixel electrode 312, and the third sub-pixel electrode 313. In addition to an emission layer, the intermediate layer 320 may include a HIL, a HTL, and/or an ETL, and layers included in this intermediate layer 320 may also have an integral shape across the first sub-pixel electrode 311, the second sub-pixel electrode 312, and the third sub-pixel electrode 313. Some of the layers included in the intermediate layer 320 may patterned and positioned on the first sub-pixel electrode 311, the second sub-pixel electrode 312, and the third sub-pixel electrode 313.

The opposite electrode 330 may be disposed on the intermediate layer 320 and may have an integral shape across the first sub-pixel electrode to the third sub-pixel electrode 311, 312, and 313.

In an embodiment, the intermediate layer 320 may include a single emission layer. The first light-emitting element LED1 to the third light-emitting element LED3 may emit blue light. In another embodiment, as described above with reference to FIGS. 4B to 4E, the intermediate layer 320 may have a stacked structure including at least two emitting units that emit light in different wavelength bands. For example, each of the intermediate layers 320 of the first light-emitting element LED1 to the third light-emitting element LED3 may include a stacked structure of emitting units that emit blue light and red light. The first light-emitting element LED1 to the third light-emitting element LED3 may emit mixed light that is a mixture of blue light and green light. Alternatively, each of the intermediate layers 320 of the first light-emitting element LED1 to the third light-emitting element LED3 may include a stacked structure of emitting units that emit blue light, green light, and yellow light. The first light-emitting element LED1 to the third light-emitting element LED3 may emit mixed light that is a mixture of blue light, green light, and yellow light. Alternatively, each of the intermediate layers 320 of the first light-emitting element LED1 to the third light-emitting element LED3 may include a stacked structure of emitting units that emit blue light, green light, and red light. The first light-emitting element LED1 to the third light-emitting element LED3 may emit white light that is a mixture of blue light, green light, and red light.

The first light-emitting element LED1 to the third light-emitting element LED3 may emit light belonging to a first wavelength band. Specifically, the first light-emitting element LED1 to the third light-emitting element LED3 may emit light belonging to the first wavelength band toward the first quantum dot layer 510, the second quantum dot layer 520, and the light-transmitting layer 530. In an embodiment, single light emitted from the first light-emitting element LED1 to the third light-emitting element LED3 may be light in a wavelength band of about 380 nanometers (nm) to about 780 nm, which corresponds to a visible light region. For example, a spectrum of the single light emitted from the first light-emitting element LED1 to the third light-emitting element LED3 may have a peak wavelength of about 380 nm to about 550 nm. In an embodiment, mixed light emitted from the first light-emitting element LED1 to the third light-emitting element LED3 may be light in a wavelength band of about 380 nm to about 780 nm.

A pixel-defining layer 210 may be disposed on the via insulating layer 205. The pixel-defining layer 210 may have sub-pixel openings corresponding to the sub-pixels. In other words, the pixel-defining layer 210 may cover an edge of each of the first sub-pixel electrode 311, the second sub-pixel electrode 312, and the third sub-pixel electrode 313, and may have a first sub-pixel opening 211 exposing a central portion of the first sub-pixel electrode 311, a second sub-pixel opening 212 exposing a central portion of the second sub-pixel electrode 312, and a third sub-pixel opening 213 exposing a central portion of the third sub-pixel electrode 313. A portion of the pixel-defining layer 210 excluding the first sub-pixel opening to the third sub-pixel opening 211, 212, and 213 is referred to as a body portion and may refer to a portion having a certain thickness. The pixel-defining layer 210 may increase a distance between the opposite electrode 330 and an edge of each of the first sub-pixel electrode 311, the second sub-pixel electrode 312, and the third sub-pixel electrode 313, thereby preventing an arc or the like from occurring at edges of the first sub-pixel electrode 311, the second sub-pixel electrode 312, and the third sub-pixel electrode 313.

The first sub-pixel opening to the third sub-pixel opening 211, 212, and 213 of the pixel-defining layer 210 may define light-emitting areas of the first light-emitting element to the third light-emitting element LED1, LED2, and LED3, respectively. For example, the first sub-pixel opening 211 of the pixel-defining layer 210 corresponding to the first light-emitting element LED1 may define a first light-emitting area, the second sub-pixel opening 212 of the pixel-defining layer 210 corresponding to the second emission layer LED2 may define a second light-emitting area, and the third sub-pixel opening 213 of the pixel-defining layer 210 corresponding to the third light-emitting element LED3 may define a third light-emitting area. This pixel-defining layer 210 may include an organic material such as polyimide or HMDSO.

Referring to FIG. 6, a first bank layer 450 may be disposed on the opposite electrode 330. A first-1 bank opening 451, a first-2 bank opening 452, and a first-3 bank opening 453 may be defined in the first bank layer 450. A portion of the first bank layer 450 excluding the first-1 bank opening to the first-3 bank opening 451, 452, and 453 is referred to as a body portion and may refer to a portion having a certain thickness. The first-1 bank opening 451 may correspond to the first sub-pixel opening 211 that exposes the first sub-pixel electrode 311 of the pixel-defining layer 210, and the first-2 bank opening 452 may correspond to the second sub-pixel opening 212 that exposes the second sub-pixel electrode 312 of the pixel-defining layer 210, and the first-3 bank opening 453 may correspond to the third sub-pixel opening 213 that exposes the third sub-pixel electrode 313 of the pixel-defining layer 210.

The first bank layer 450 may include various materials, including an organic material or an inorganic material. For example, the first bank layer 450 may include an inorganic material such as silicon oxide, silicon nitride, or silicon oxynitride, or an organic material such as BCB or HMDSO. In an embodiment, the first bank layer 450 may include a light-shielding material so as to function as a light-shielding layer. For example, the light-shielding material may include at least one of black pigment, black dye, black particles, or metal particles.

The first bank layer 450 may prevent color mixing caused by the inflow of light emitted from the first light-emitting element to the third light-emitting element LED1, LED2, and LED3 to the functional layer 500 of another neighboring sub-pixel other than corresponding functional layers 500 (see FIG. 2).

The first light-emitting element to the third light-emitting element LED1, LED2, and LED3, which are organic light-emitting diodes, may be easily deteriorated by moisture or oxygen. Accordingly, the encapsulation layer 400 may be disposed on the first light-emitting element to the third light-emitting element LED1, LED2, and LED3. The encapsulation layer 400 may be arranged to cover the first bank layer 450 and the first light-emitting element to the third light-emitting element LED1, LED2, and LED3. The encapsulation layer 400 may protect the first light-emitting element to the third light-emitting element LED1, LED2, and LED3 from moisture or oxygen from the outside. The encapsulation layer 400 may include at least one inorganic encapsulation layer and at least one organic encapsulation layer. For example, the encapsulation layer 400 may include a first inorganic encapsulation layer 410, a second inorganic encapsulation layer 430, and an organic encapsulation layer 420 therebetween.

Each of the first inorganic encapsulation layer 410 and the second inorganic encapsulation layer 430 may include one or more inorganic insulating materials. The inorganic insulating materials may include one or more inorganic insulating materials such as silicon oxide, silicon nitride, silicon oxynitride, aluminum oxide, titanium oxide, tantalum oxide, hafnium oxide, or zinc oxide. The organic encapsulation layer 420 may include a polymer-based material. The polymer-based material may include acryl-based resin, epoxy-based resin, polyimide, and polyethylene. For example, the organic encapsulation layer 420 may include acryl-based resin such as poly (methyl methacrylate) or polyacrylic acid. The organic encapsulation layer 420 may be formed by curing a monomer or applying a polymer.

Because the first inorganic encapsulation layer 410 is formed by chemical vapor deposition and has an approximately uniform thickness, an upper surface of the first inorganic encapsulation layer 410 may not be flat. However, an upper surface of the organic encapsulation layer 420 has an approximately flat shape, and accordingly, an upper surface of the second inorganic encapsulation layer 430 that is on the organic encapsulation layer 420 may also have an approximately flat shape.

A second bank layer 540 may be disposed on the encapsulation layer 400. A second-1 bank opening 541, a second-2 bank opening 542, and a second-3 bank opening 543 may be defined in the second bank layer 540. A portion of the second bank layer 540 excluding the second-1 bank opening to the second-3 bank opening 541, 542, and 543 is referred to as a body portion and may refer to a portion having a certain thickness. The second-1 bank opening 541 may correspond to the first sub-pixel opening 211 that exposes the first sub-pixel electrode 311 of the pixel-defining layer 210, and the second-2 bank opening 542 may correspond to the second sub-pixel opening 212 that exposes the second sub-pixel electrode 312 of the pixel-defining layer 210, and the second-3 bank opening 543 may correspond to the third sub-pixel opening 213 that exposes the third sub-pixel electrode 313 of the pixel-defining layer 210.

The second bank layer 540 may include various materials, including an organic material or an inorganic material. For example, the second bank layer 540 may include an inorganic material such as silicon oxide, silicon nitride, or silicon oxynitride, or an organic material such as BCB or HMDSO. In some cases, the second bank layer 540 may include a light-shielding material so as to function as a light-shielding layer. For example, the light-shielding material may include at least one of black pigment, black dye, black particles, or metal particles.

The second bank layer 540 may prevent light converted and scattered in the first quantum dot layer 510, the second quantum dot layer 520, and the light-transmitting layer 530 described below from traveling to other areas. In addition, the second bank layer 540 may prevent reflection of external light together with the color filter layer 600 (see FIG. 2), so that a contrast of the display apparatus may be improved.

The first quantum dot layer 510 may be positioned in the second-1 bank opening 541 of the second bank layer 540. The second quantum dot layer 520 may be positioned in the second-2 bank opening 542 of the second bank layer 540. The light-transmitting layer 530 may be positioned in the second-3 bank opening 543. Materials included in the first quantum dot layer 510, the second quantum dot layer 520, and the light-transmitting layer 530 are as described above with reference to FIG. 3. Each of the first quantum dot layer 510, the second quantum dot layer 520, and the light-transmitting layer 530 may be formed through an inkjet method. The first quantum dot 512 and the second quantum dots 522 included in the first quantum dot layer 510 and the second quantum dot layer 520, respectively, refer to crystals of a semiconductor compound and may include any material that emits light of various light-emitting wavelengths, depending on a size of a crystal. A diameter of this quantum dot may be, for example, about 1 nm to about 10 nm.

The first quantum dot layer 510 may receive light belonging to the first wavelength band from the first light-emitting element LED1 and convert part of the received light of a wavelength belonging to the first wavelength band into light of a wavelength belonging to a second wavelength band. For example, a spectrum of light belonging to the second wavelength band may have a peak wavelength of about 550 nm to about 780 nm, and a full width at half maximum may be about 50 nm or less. The second quantum dot layer 520 may receive light belonging to the first wavelength band from the second emission layer LED2 and convert part of the received light of a wavelength belonging to the first wavelength band into light of a wavelength belonging to a third wavelength band. For example, a spectrum of light belonging to the third wavelength band may have a peak wavelength of about 500 nm to about 550 nm, and a full width at half maximum may be about 50 nm or less.

A wavelength band to which target wavelengths converted by the first quantum dot layer 510 and the second quantum dot layer 520, respectively, belong and a wavelength band to which a wavelength after conversion belongs may be modified differently.

Each of the first quantum dot layer 510, the second quantum dot layer 520, the light-transmitting layer 530, and the second bank layer 540 may be arranged to be in contact with the second inorganic encapsulation layer 430 of the encapsulation layer 400.

In an embodiment, a first passivation layer 910 may be disposed on the functional layer 500 (see FIG. 2). The first quantum dot layer 510, the second quantum dot layer 520, the light-transmitting layer 530, and the second bank layer 540 may include an organic material, and may be covered by the first passivation layer 910 to prevent moisture infiltration into the organic material. For example, a second passivation layer 930 may include an inorganic material such as silicon oxide, silicon nitride, or silicon oxynitride, and may be formed by a chemical vapor deposition (CVD) method.

The color filter layer 600 may be disposed between the second substrate 700 and the second bank layer 540. The second substrate 700 may be a glass substrate containing SiO₂ as a main component. In another embodiment, the second substrate 700 may include polymer resin.

When viewed from a direction perpendicular to the first substrate 100 (i.e., plan view), the first color filter 610 may be positioned in the first sub-pixel PX1 to overlap the first light-emitting element LED1, the second color filter 620 may be positioned in the second sub-pixel PX2 to overlap the second emission layer LED2, and the third color filter 630 may be positioned in the third sub-pixel PX3 to overlap the third light-emitting element LED3 in a plan view.

In an embodiment, the first color filter 610 may transmit red light emitted from the first quantum dot layer 510. For example, the first color filter 610 may receive light in a second wavelength band from the first quantum dot layer 510 and pass through part of the received light. For example, the first color filter 610 may transmit light of about 550 nm to about 780 nm. The second color filter 620 may transmit green light emitted from the second quantum dot layer 520. For example, the second color filter 620 may receive light in a third wavelength band from the second quantum dot layer 520 and pass through part of the received light. For example, the second color filter 620 may transmit light of about 470 nm to about 600 nm. The third color filter 630 may transmit blue light from among light emitted from the third light-emitting element LED3. For example, the third color filter 630 may be emitted from the third light-emitting element LED3 and may receive light in the first wavelength band passing through the light-transmitting layer 530 and transmit part of the received light. For example, the third color filter 630 may transmit light of about 380 nm to about 500 nm.

As shown in FIG. 6, the third color filter 630 may have a second filter opening 602 corresponding to the second emission layer LED2. The second color filter 620 may fill in at least this second filter opening 602 of the third color filter 630.

In addition, the second color filter 620 may have a third filter opening 603 corresponding to the third light-emitting element LED3. The third color filter 630 may fill in at least this third filter opening 603 of the second color filter 620.

The third color filter 630 may have a first filter opening 601 corresponding to the first light-emitting element LED1. The first color filter 610 may fill in at least this first filter opening 601 of the third color filter 630.

Portions in which at least two color filters overlap each other constitute a “light-shielding portion”, and the light-shielding portion may serve as a black matrix. For example, in a portion in which the first color filter 610 and the second color filter 620, which transmit light of different colors from each other, overlap each other in a plan view, light capable of passing through both the first color filter 610 and the second color filter 620 does not exist theoretically.

In FIG. 6, an embodiment is illustrated in which the third color filter 630, the first color filter 610, and the second color filter 620 are sequentially disposed on the second substrate 700. However, a stacked order of the first color filter 610, the second color filter 620, and the third color filter 630 may be changed.

A second passivation layer 930 may be positioned between the second bank layer 540 and the first color filter 610, the second color filter 620, and the third color filter 630. For example, a second passivation layer 930 may include an inorganic material such as silicon oxide, silicon nitride, or silicon oxynitride, and may be formed by a CVD method. The second passivation layer 930 may prevent or minimize defects from occurring due to permeation of impurities such as gas generated in the first color filter 610, the second color filter 620, and/or the third color filter 630 into the first quantum dot layer 510, the second quantum dot layer 520, and an emission layer of an organic light-emitting element thereunder.

The low-refractive layer 920 may be positioned between the second passivation layer 930 and the first color filter 610, the second color filter 620, and the third color filter 630. This low-refractive layer 920 may include an inorganic material such as silicon oxide, silicon nitride, or silicon oxynitride, and may be formed by a CVD method. When the low-refractive layer 920 is included, utilization of light may be increased through reflection and re-incidence, thereby further improving light efficiency.

Referring to FIGS. 2 and 6, the light-emitting panel 1000 and the color filter panel 2000 are bonded to each other by a sealant or the like, and then, the filler 800 may fill in a space therebetween. The filler 800 may fill the space between the light-emitting panel 1000 and the color filter panel 2000.

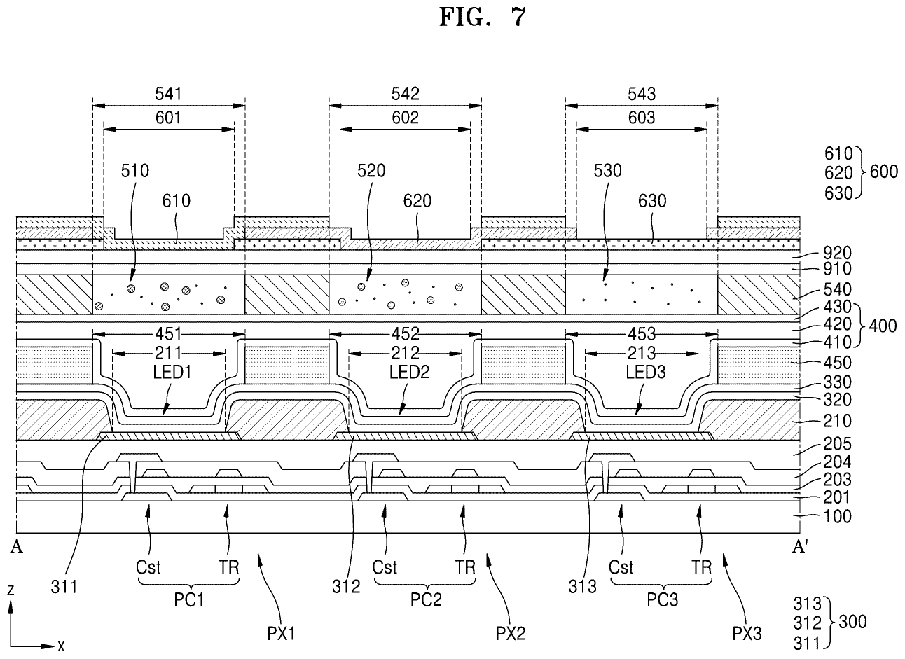

FIG. 7 is a cross-sectional view schematically illustrating a display apparatus according to another embodiment. Hereinbelow, differences from the display apparatus of the embodiment of FIG. 6 are mainly described.

Referring to FIGS. 2 and 7, the display apparatus may include the first substrate 100, the light-emitting element layer 300 disposed on the first substrate 100 and including the first light-emitting element to the third light-emitting element LED1, LED2, and LED3, the first bank layer 450 that is on the light-emitting element layer 300, the encapsulation layer 400 disposed on the first bank layer 450 and including the first and second inorganic encapsulation layers 410 and 430 and the organic encapsulation layer 420, the functional layer 500 disposed on the encapsulation layer 400 and including the first quantum dot layer 510, the second quantum dot layer 520, and the light-transmitting layer 530, and the color filter layer 600 disposed on the functional layer 500.

In an embodiment, the display apparatus may not include a second substrate arranged to face the first substrate 100, and may include only one substrate (i.e., the first substrate 100). The functional layer 500 and the color filter layer 600 may be disposed on the first substrate 100. The display apparatus may not include a filler.

The functional layer 500 and the color filter layer 600 may be sequentially formed on the encapsulation layer 400. The third color filter 630, the second color filter 620, and the first color filter 610 of the color filter layer 600 may be sequentially stacked on the functional layer 500.

In an embodiment, the first passivation layer 910 may be disposed between the color filter layer 600 and the functional layer 500. The low-refractive layer 920 may be disposed between the first passivation layer 910 and the color filter layer 600.

Hereinbelow, a description is made based on the stacked structure of FIG. 6.

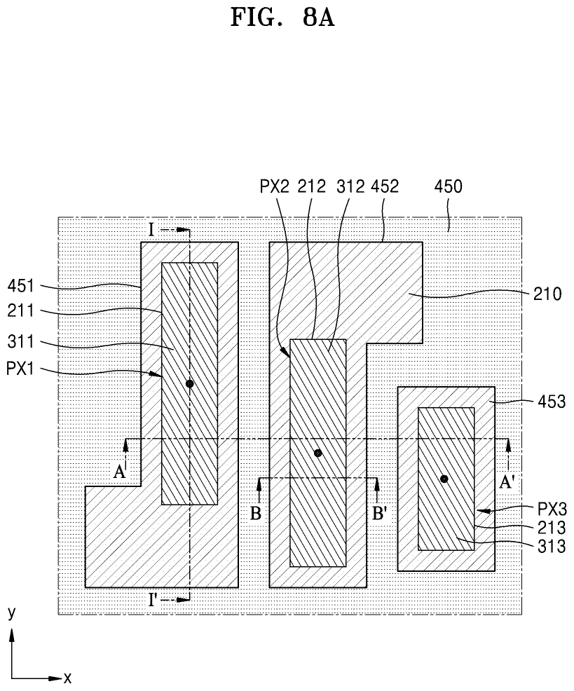

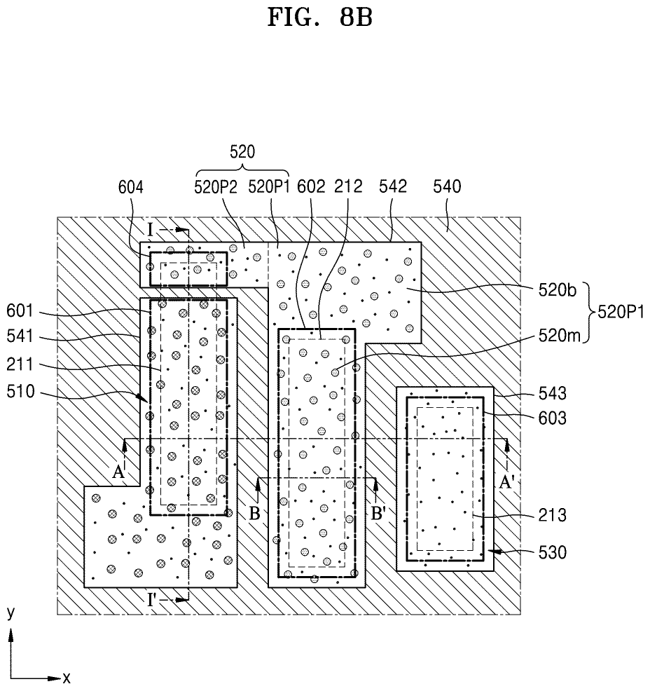

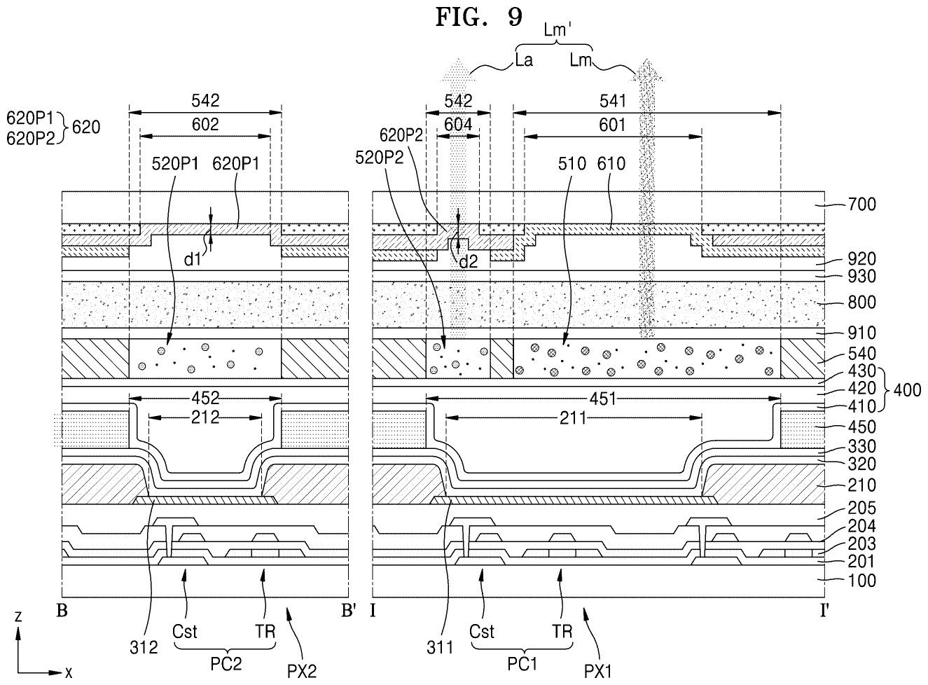

FIGS. 8A and 8B are plan views schematically illustrating a portion of a display apparatus according to an embodiment. FIGS. 8A shows a portion of the display apparatus, including the first to third sub-pixel electrodes 311, 312, and 313, the pixel-defining layer 210, and the first bank layer 450. FIG. 8B shows a portion of the display apparatus, including the second bank layer 540, the first quantum dot layer 510, the second quantum dot layer 520, and the light-transmitting layer 530. FIG. 9 is a cross-sectional view taken along lines I-I′ and B-B′ of FIGS. 8A and 8B. Meanwhile, FIG. 6 described above corresponds to a cross-sectional view taken along line A-A′ of FIGS. 8A and 8B. As used herein, the “plan view” is a view in a thickness direction (z-axis direction) of the first substrate 100.

Referring to FIGS. 8A and 8B, the first sub-pixel PX1 to the third sub-pixel PX3 may be arranged in a striped manner. In other words, the first sub-pixel PX1, the second sub-pixel PX2, and the third sub-pixel PX3 may be arranged in order in an x-axis direction. However, one or more embodiments are not limited thereto. The first sub-pixel PX1 to the third sub-pixel PX3 may be arranged in an s-stripe manner, a mosaic method, or a PenTile™ method in another embodiment.

When viewed from a direction perpendicular to the first substrate 100 (i.e., plan view), the first sub-pixel PX1, the second sub-pixel PX2, and the third sub-pixel PX3 may have a polygonal shape. In FIGS. 8A and 8B, each of portions of the first sub-pixel electrode 311 of the first sub-pixel PX1, the second sub-pixel electrode 312 of the second sub-pixel PX2, and the third sub-pixel electrode 313 of the third sub-pixel PX3 exposed by the pixel-defining layer 210 has a rectangular shape. However, one or more embodiments are not limited thereto. Each of portions of the first sub-pixel electrode 311 of the first sub-pixel PX1, the second sub-pixel electrode 312 of the second sub-pixel PX2, and the third sub-pixel electrode 313 of the third sub-pixel PX3 exposed by the pixel-defining layer 210 may have a circular shape, an elliptical shape, or a polygonal shape other than a rectangle.

The first sub-pixel PX1 may have the first sub-pixel electrode 311, the second sub-pixel PX2 may have the second sub-pixel electrode 312, and the third sub-pixel PX3 may have the third sub-pixel electrode 313. The pixel-defining layer 210 may cover an edge of each of the first sub-pixel electrode 311, the second sub-pixel electrode 312, and the third sub-pixel electrode 313. In other words, the first sub-pixel opening 211 exposing a center of the first sub-pixel electrode 311, the second sub-pixel opening 212 exposing a center of the second sub-pixel electrode 312, and the third sub-pixel opening 213 exposing a center of the third sub-pixel electrode 313 may be defined in the pixel-defining layer 210.

The first bank layer 450 may be disposed on the pixel-defining layer 210. The first-1 bank opening 451, the first-2 bank opening 452, and the first-3 bank opening 453 may be defined in the first bank layer 450. The first-1 bank opening 451 may correspond to the first sub-pixel opening 211 defined in the pixel-defining layer 210, the first-2 bank opening 452 may correspond to the second sub-pixel opening 212 defined in the pixel-defining layer 210, and the first-3 bank opening 453 may correspond to the third sub-pixel opening 213 defined in the pixel-defining layer 210.

The body portion of the first bank layer 450 may be arranged to surround the first sub-pixel opening to the third sub-pixel opening 211, 212, and 213. When viewed from a direction perpendicular to the first substrate 100 (i.e., plan view), an area of the first-1 bank opening 451 defined in the first bank layer 450 may be greater than an area of the first sub-pixel opening 211 defined in the pixel-defining layer 210, an area of the first-2 bank opening 452 may be greater than an area of the second sub-pixel opening 212 defined in the pixel-defining layer 210, and an area of the first-3 bank opening 453 may be greater than an area of the third sub-pixel opening 213 defined in the pixel-defining layer 210.

The body portion of the first bank layer 450 may include a light-shielding material. In other words, light emitted from the first light-emitting element LED1 may move within the first-1 bank opening 451. Light emitted from the second emission layer LED2 may move within the first-1 bank opening 451. Light emitted from the third light-emitting element LED3 may move within the first-3 bank opening 453.

Referring to FIG. 8B, the second-1 bank opening 541, the second-2 bank opening 542, and the second-3 bank opening 543 may be defined in the second bank layer 540. The second-1 bank opening 541 may correspond to the first sub-pixel opening 211 defined in the pixel-defining layer 210, the second-2 bank opening 542 may correspond to the second sub-pixel opening 212 defined in the pixel-defining layer 210, and the second-3 bank opening 543 may correspond to the third sub-pixel opening 213 defined in the pixel-defining layer 210.

The first quantum dot layer 510 may be positioned in the second-1 bank opening 541. The second quantum dot layer 520 may be positioned in the second-2 bank opening 542. The light-transmitting layer 530 may be arranged in the second-3 bank opening 543. A shape of an edge of the second-1 bank opening 541 may be identical or similar to a shape of an edge of the first quantum dot layer 510. A shape of an edge of the second-2 bank opening 542 may be identical or similar to a shape of an edge of the second quantum dot layer 520. A shape of an edge of the second-3 bank opening 543 may be identical or similar to a shape of an edge of the light-transmitting layer 530.

When viewed from a direction perpendicular to the first substrate 100 (i.e., plan view), the second quantum dot layer 520 may include a first portion 520P1 and a second portion 520P2. The first portion 520P1 of the second quantum dot layer 520 may include a first-1 portion 520m overlapping the second sub-pixel opening 212 in a plan view and a first-2 portion 520b extending in an x direction and in a y direction from the first-1 portion 520m. The second portion 520P2 of the second quantum dot layer 520 may be a portion extending from the first portion 520P1 (e.g., the first-2 portion 520b) toward a direction in which the second sub-pixel opening 212 faces the first sub-pixel opening 211 (e.g., a-x direction). The first-2 portion 520b and the second portion 520P2 of the second quantum dot layer 520 may be portions formed in a space that ensures an impact margin when the second quantum dot layer 520 is formed in the second-2 bank opening 542. The second portion 520P2 of the second quantum dot layer 520 may be arranged adjacent to the first quantum dot layer 510.

In an embodiment, the first quantum dot layer 510 may overlap the first sub-pixel opening 211 of the pixel-defining layer 210. The second portion 520P2 of the second quantum dot layer 520 may overlap the first sub-pixel opening 211 of the pixel-defining layer 210 in a plan view. In other words, the first sub-pixel opening 211 of the pixel-defining layer 210 may overlap the first quantum dot layer 510 and the second portion 520P2 of the second quantum dot layer 520. The first portion 520P1 of the second quantum dot layer 520 may overlap the second sub-pixel opening 212 defined in the pixel-defining layer 210. The light-transmitting layer 530 may overlap the third sub-pixel opening 213 defined in the pixel-defining layer 210 in a plan view.

The first quantum dot layer 510 may overlap the first-1 bank opening 451 defined in the first bank layer 450. The second portion 520P2 of the second quantum dot layer 520 may overlap the first-1 bank opening 451 defined in the first bank layer 450. In other words, the first-1 bank opening 451 defined in the first bank layer 450 may overlap the first quantum dot layer 510 and the second portion 520P2 of the second quantum dot layer 520. The first portion 520P1 of the second quantum dot layer 520 may overlap the first-2 bank opening 452 defined in the first bank layer 450. The light-transmitting layer 530 may overlap the first-3 bank opening 453 in a plan view.

Referring to FIGS. 6, 8B, and 9, the second color filter 620 may have the third filter opening 603 corresponding to the light-transmitting layer 530. The third filter opening 603 defined in the second color filter 620 may overlap the third sub-pixel opening 213 defined in the pixel-defining layer 210. The third filter opening 603 defined in the second color filter 620 may define an area of the third sub-pixel PX3. In addition, the third color filter 630 may have the second filter opening 602 corresponding to the first portion 520P1 of the second quantum dot layer 520. The second filter opening 602 defined in the third color filter 630 may overlap the second sub-pixel opening 212 defined in the pixel-defining layer 210 in a plan view. The second filter opening 602 defined in the third color filter 630 may define an area of the second sub-pixel PX2.

Meanwhile, the third color filter 630 may have the first filter opening 601 corresponding to the first quantum dot layer 510 and a fourth filter opening 604 corresponding to the second portion 520P2 of the second quantum dot layer 520. In a plan view, the fourth filter opening 604 may be arranged adjacent to the first filter opening 601. A distance from the fourth filter opening 604 to the first filter opening 601 may be less than a distance from the fourth filter opening 604 to the second filter opening 602. The first filter opening 601 and the fourth filter opening 604 of the third color filter 630 may overlap the first sub-pixel opening 211 defined in the pixel-defining layer 210 in a plan view. The first filter opening 601 and the third color filter 630 defined in the third color filter 630 may define areas included in an area of the first sub-pixel PX1.

The third color filter 630 may fill in the third filter opening 603 defined in the second color filter 620. The first color filter 610 may fill in the first filter opening 601 defined in the third color filter 630. In an embodiment, referring to FIG. 9, the second color filter 620 may include a first filter portion 620P1 and a second filter portion 620P2. The first filter portion 620P1 and the second filter portion 620P2 of the second color filter 620 may include the same composition. A thickness d2 of the second filter portion 620P2 of the second color filter 620 may be greater than a thickness d1 of the first filter portion 620P1 of the second color filter 620 in the z-axis direction. This second color filter 620 may be formed by using a halftone mask. The first filter portion 620P1 of the second color filter 620 may fill in the second filter opening 602 defined in the third color filter 630. The second filter portion 620P2 of the second color filter 620 may fill in the fourth filter opening 604 defined in the third color filter 630.

Referring to FIG. 9, in the area of the first sub-pixel PX1, light generated on the first sub-pixel opening 211 of the pixel-defining layer 210 (e.g., light in the first wavelength band emitted from the first light-emitting element LED1, including blue light) may move within the first-1 bank opening 451 defined in the first bank layer 450 and may be incident on the first quantum dot layer 510 and the second portion 520P2 of the second quantum dot layer 520. First red light Lm converted in the first quantum dot layer 510 and passing through the first color filter 610 (e.g., light passing through the first color filter 610 from among light in the second wavelength band that is converted in the first quantum dot layer 510) may be emitted from the first sub-pixel PX1. Second green light La converted in the second portion 520P2 of the second quantum dot layer 520 and passing through the second filter portion 620P2 of the second color filter 620 (e.g., light passing through the second filter portion 620P2 of the second color filter 620 from among light in the third wavelength band that is converted in the second portion 520P2 of the second quantum dot layer 520) may be emitted from the first sub-pixel PX1. Light Lm′ emitted from the area of the first sub-pixel PX1 may be a mixture of the first red light Lm and the second green light La.

Meanwhile, a color gamut of the display apparatus 1 may be evaluated by a color gamut of the BT2020 standard and a color gamut of the digital cinema initiatives (DCI) standard. BT2020 is a standard presented by the International Telecommunication Union (ITU), and the color gamut of the BT2020 standard may refer to the consistency of a color space of the display apparatus with a color space based on BT2020 in the CIE color coordinates. In addition, DCI is a standard for digital movie projection in the American film industry, and the color gamut of the DCI standard may refer to the consistency of a color space of the display apparatus with a color space based on DCI in the CIE color coordinates.

The first quantum dot layer 510 of the display apparatus 1 may be designed to emit red light with a high color gamut based on BT2020. However, according to an embodiment, without changing a material such as quantum dots of the first quantum dot layer 510, green light emitted from a portion of the second quantum dot layer 520 (e.g., the second portion 520P2 of the second quantum dot layer 520) may pass through a color filter under appropriate conditions and may be mixed with red light emitted from the first quantum dot layer 510 in the area of the first sub-pixel PX1, thereby improving a color gamut that is based on the DCI standard.

In an embodiment, the green light emitted from the second quantum dot layer 520 may have a wavelength band of a shorter wavelength than a wavelength band of green light to be mixed with the first red light Lm of the area of the first sub-pixel PX1, so as to improve the color gamut based on DCI.

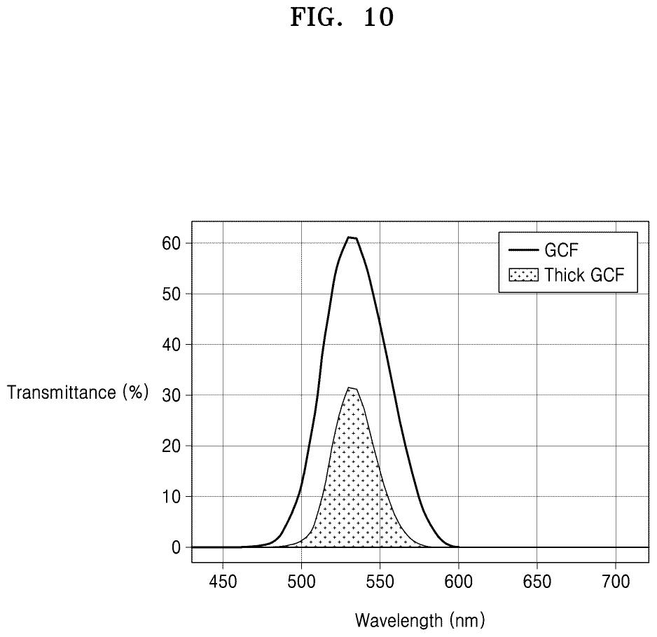

FIG. 10 is a graph showing a light transmission spectrum of the first filter portion 620P1 (noted as “G-CF”) of the second color filter 620 and the second filter portion 620P2 (noted as “Thick GCF”) of the second color filter 620. As shown in FIG. 10, the second filter portion 620P2 of the second color filter 620 has a greater thickness than the first filter portion 620P1 of the second color filter 620, so that the second green light La emitted from the second quantum dot layer 520 and passing through the second filter portion 620P2 of the second color filter 620 may have lower light efficiency than green light passing through the first filter portion 620P1 of the second color filter 620.

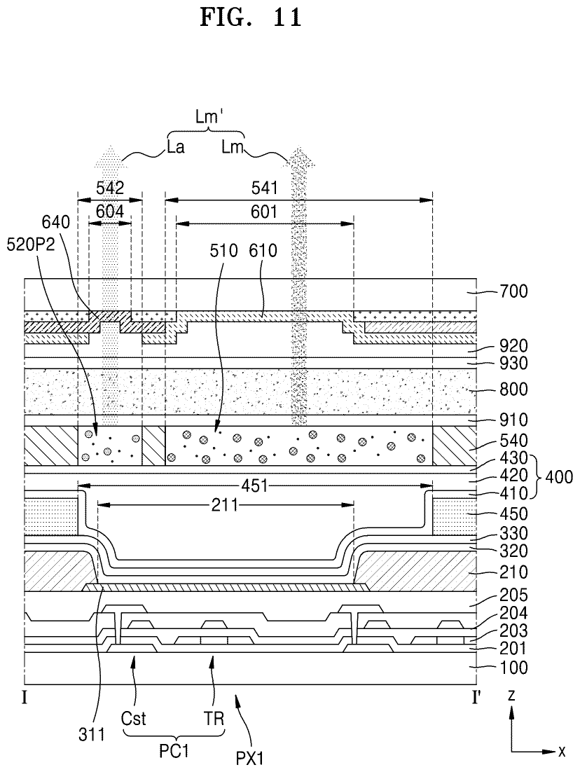

FIG. 11 shows a cross-sectional view of a modification of FIG. 9, taken along line I-I′ of FIGS. 8A and 8B. Hereinbelow, differences from FIG. 9 are mainly described, and redundant descriptions are omitted.

Referring to FIGS. 6, 8B, and 11, the third color filter 630 may have the first filter opening 601 corresponding to the first quantum dot layer 510, and the fourth filter opening 604 corresponding to the second portion 520P2 of the second quantum dot layer 520. In a plan view, the fourth filter opening 604 may be arranged adjacent to the first filter opening 601. A distance from the fourth filter opening 604 to the first filter opening 601 may be less than a distance from the fourth filter opening 604 to the second filter opening 602. The first filter opening 601 and the fourth filter opening 604 of the third color filter 630 may overlap the first sub-pixel opening 211 defined in the pixel-defining layer 210 in a plan view. The first filter opening 601 and the third color filter 630 defined in the third color filter 630 may define areas included in an area of the first sub-pixel PX1.

The third color filter 630 may fill in the third filter opening 603 defined in the second color filter 620. The first color filter 610 may fill in the first filter opening 601 defined in the third color filter 630. In an embodiment, referring to FIG. 11, the second color filter 620 may fill in the second filter opening 602. A fourth color filter 640 may fill in the fourth filter opening 604. The fourth color filter 640 may include a material different from a material of the second color filter 620. A light transmission spectrum of the fourth color filter 640 may be shifted toward a longer wavelength than a light transmission spectrum of the second color filter 620. For example, the fourth color filter 640 may transmit light of about 480 nm to about 620 nm. To form the fourth color filter 640, a new color filter material and a separate mask may be required.

Referring to FIG. 11, in the area of the first sub-pixel PX1, light generated on the first sub-pixel opening 211 of the pixel-defining layer 210 (e.g., light in the first wavelength band emitted from the first light-emitting element LED1, including blue light) may move within the first-1 bank opening 451 defined in the first bank layer 450 and may be incident on the first quantum dot layer 510 and the second portion 520P2 of the second quantum dot layer 520. First red light Lm converted in the first quantum dot layer 510 and passing through the first color filter 610 (e.g., light passing through the first color filter 610 from among light in the second wavelength band that is converted in the first quantum dot layer 510) may be emitted from the first sub-pixel PX1. Second green light La converted in the second portion 520P2 of the second quantum dot layer 520 and passing through the fourth color filter 640 (e.g., light passing through the fourth color filter 640 from among light in the third wavelength band that is converted in the second portion 520P2 of the second quantum dot layer 520) may be emitted from the first sub-pixel PX1. Light Lm′ emitted from the area of the first sub-pixel PX1 may be a mixture of the first red light Lm and the second green light La.

The first quantum dot layer 510 of the display apparatus 1 may be designed to emit red light with a high color gamut based on BT2020. However, according to an embodiment, without changing a material such as quantum dots of the first quantum dot layer 510, green light emitted from a portion of the second quantum dot layer 520 (e.g., the second portion 520P2 of the second quantum dot layer 520) may pass through a color filter under appropriate conditions and may be mixed with red light emitted from the first quantum dot layer 510 in the area of the first sub-pixel PX1, thereby improving a color gamut that is based on the DCI standard.

In an embodiment, the green light emitted from the second quantum dot layer 520 may have a wavelength band of a shorter wavelength than a wavelength band of green light to be mixed with the first red light Lm of the area of the first sub-pixel PX1, so as to improve the color gamut based on DCI.

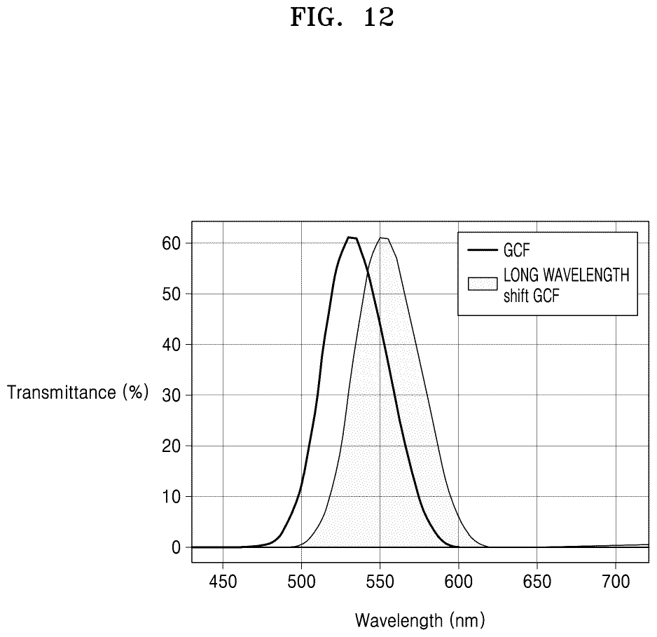

FIG. 12 is a graph showing transmission spectra of the second color filter 620 (noted as “G-CF”) and the fourth color filter 640 (noted as “long wavelength shift G-CF). As shown in FIG. 12, the second green light La emitted from the second quantum dot layer 520 and passing through the fourth color filter 640 may have a wavelength band of a longer wavelength than green light passing through the first filter portion 620P1 of the second color filter 620.

Thus, in the display apparatus, a color gamut based on DCI of the light Lm′ emitted from the first sub-pixel PX1 may be excellent compared to the existing first red light Lm.

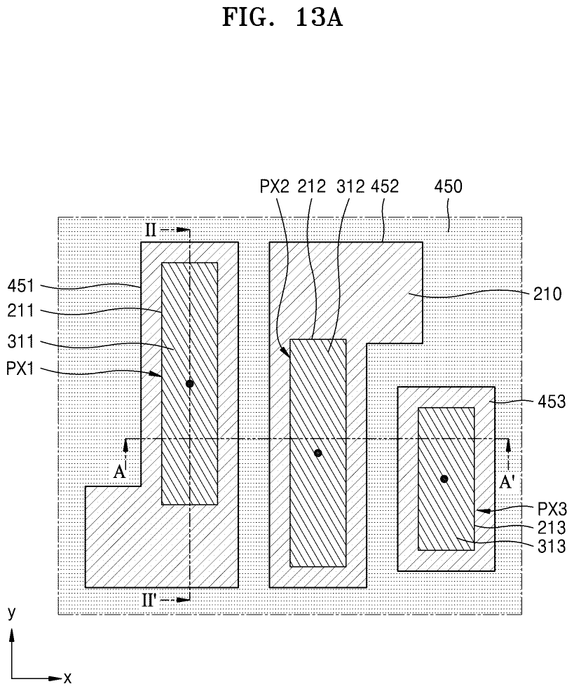

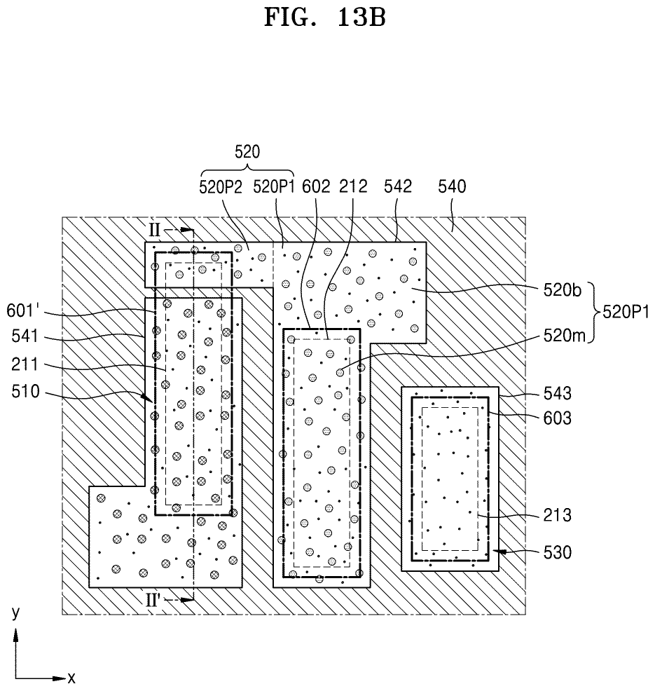

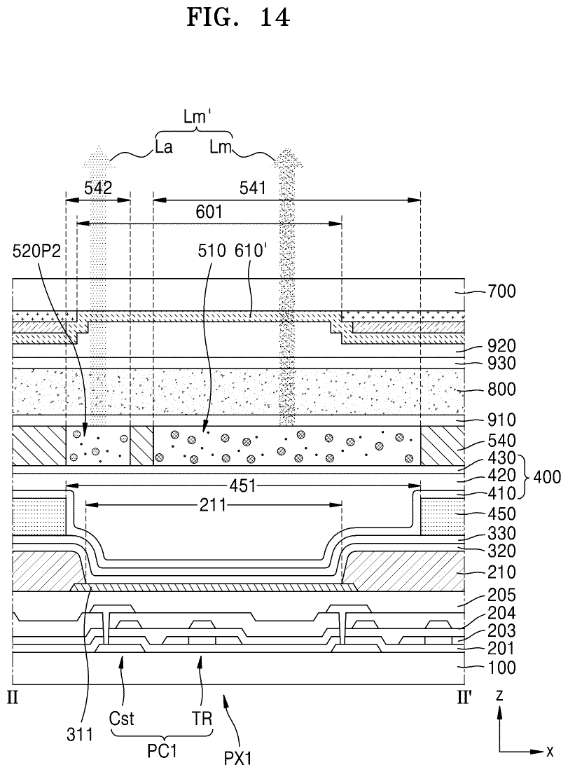

FIGS. 13A and 13B are plan views schematically illustrating a portion of a display apparatus according to an embodiment. FIGS. 13A shows a portion of the display apparatus, including the first to third sub-pixel electrodes 311, 312, and 313, the pixel-defining layer 210, and the first bank layer 450. FIG. 13B shows a portion of the display apparatus, including the second bank layer 540, the first quantum dot layer 510, the second quantum dot layer 520, and the light-transmitting layer 530. FIG. 14 is a cross-sectional view taken along line II-II' of FIGS. 13A and 13B. FIGS. 13A, 13B, and 14A are modifications of FIGS. 8A, 8B, and 11, respectively, and differences are mainly described below.

Referring to FIGS. 13A, 13B, and 14, the second color filter 620 may have the third filter opening 603 corresponding to the light-transmitting layer 530. The third filter opening 603 defined in the second color filter 620 may overlap the third sub-pixel opening 213 defined in the pixel-defining layer 210 in a plan view. The third filter opening 603 defined in the second color filter 620 may define the area of the third sub-pixel PX3.

In addition, the third color filter 630 may have the second filter opening 602 corresponding to the first portion 520P1 of the second quantum dot layer 520. The second filter opening 602 defined in the third color filter 630 may overlap the second sub-pixel opening 212 defined in the pixel-defining layer 210. The second filter opening 602 defined in the third color filter 630 may define the area of the second sub-pixel PX2.

Meanwhile, the third color filter 630 may have a first filter opening 601′ corresponding to the first quantum dot layer 510 and the second portion 520P2 of the second quantum dot layer 520. In other words, the first filter opening 601′ may overlap the first quantum dot layer 510 and the second portion 520P2 of the second quantum dot layer 520. The first filter opening 601′ defined in the third color filter 630 may overlap the first sub-pixel opening 211 defined in the pixel-defining layer 210 in a plan view. The first filter opening 601′ defined in the third color filter 630 may define the area of the first sub-pixel PX1.

The third color filter 630 may fill in the third filter opening 603 defined in the second color filter 620. The second color filter 620 may fill in the second filter opening 602 defined in the third color filter 630. A first color filter 610′ may fill in the first filter opening 601′ defined in the third color filter 630.

The first color filter 610′ of FIG. 14 may include a composition different from a composition of the first color filter 610 of FIG. 9. A light transmission spectrum of the first color filter 610′ of FIG. 14 may be shifted toward a shorter wavelength than the light transmission spectrum of the first color filter 610 of FIG. 9. For example, the first color filter 610 may transmit light of about 530 nm to about 780 nm.

Referring to FIG. 14, in the area of the first sub-pixel PX1, light generated on the first sub-pixel opening 211 of the pixel-defining layer 210 (e.g., light in the first wavelength band emitted from the first light-emitting element LED1, including blue light) may move within the first-1 bank opening 451 defined in the first bank layer 450 and may be incident on the first quantum dot layer 510 and the second portion 520P2 of the second quantum dot layer 520. First red light Lm converted in the first quantum dot layer 510 and passing through the first color filter 610′ (e.g., light passing through the first color filter 610′ from among light in the second wavelength band that is converted in the first quantum dot layer 510) may be emitted from the first sub-pixel PX1. Second green light La converted in the second portion 520P2 of the second quantum dot layer 520 and passing through the first color filter 610′ (e.g., light passing through the first color filter 610′ from among light in the third wavelength band that is converted in the second portion 520P2 of the second quantum dot layer 520) may be emitted from the first sub-pixel PX1. Light Lm′ emitted from the area of the first sub-pixel PX1 may be a mixture of the first red light Lm and the second green light La.

The first quantum dot layer 510 of the display apparatus 1 may be designed to emit red light with a high color gamut based on BT2020. However, according to an embodiment, without changing a material such as quantum dots of the first quantum dot layer 510, green light emitted from a portion of the second quantum dot layer 520 (e.g., the second portion 520P2 of the second quantum dot layer 520) may pass through a color filter under appropriate conditions and may be mixed with red light emitted from the first quantum dot layer 510 in the area of the first sub-pixel PX1, thereby improving a color gamut that is based on the DCI standard.

In an embodiment, the green light emitted from the second quantum dot layer 520 may have a wavelength band of a shorter wavelength than a wavelength band of green light to be mixed with the first red light Lm of the area of the first sub-pixel PX1, so as to improve the color gamut based on DCI.

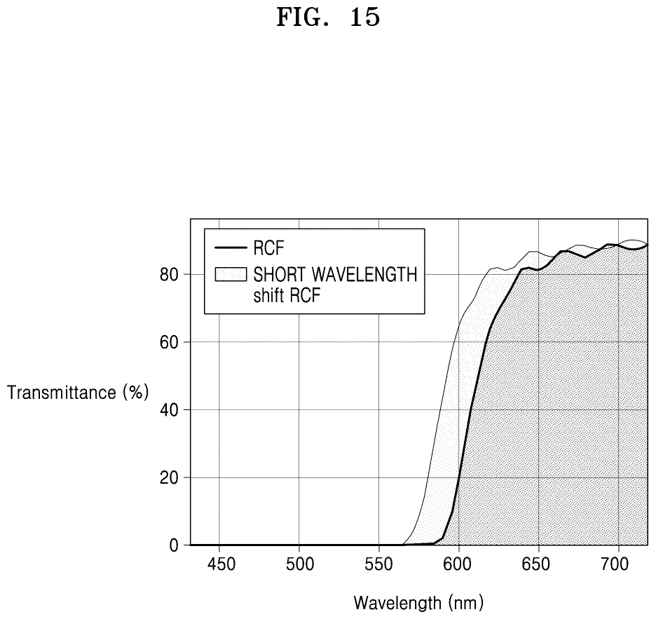

FIG. 15 is a graph showing transmission spectra of the first color filter 610 (noted as “R-CF”) of FIG. 9 and the first color filter 610′ (noted as “short wavelength shift RCF”) of FIG. 14. As shown in FIG. 15, the first color filter 610′ may transmit light in a wavelength band of a shorter wavelength than the first color filter 610 (see FIG. 9). The first color filter 610′ may transmit red light emitted from the first quantum dot layer 510 and some of green light emitted from the second portion 520P2 of the second quantum dot layer 520. The second green light La passing through the first color filter 610′ may correspond to light belonging to a wavelength band of a long wavelength from among the green light emitted from the second quantum dot layer 520.

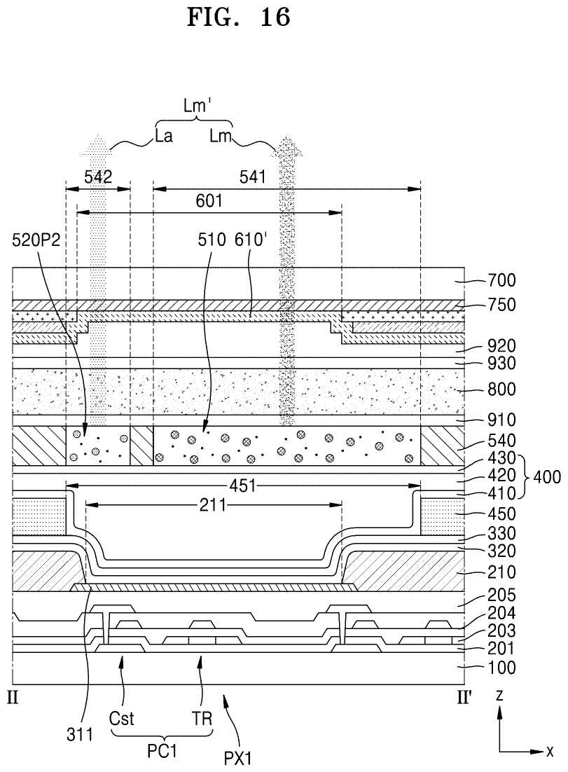

FIG. 16 shows a cross-sectional view of a display apparatus according to an embodiment. FIG. 16 is a modification of FIG. 14, and differences from FIG. 14 are mainly described.

Referring to FIG. 16, a filter layer 750 may be further disposed between the color filter layer 600 and the second substrate 700, where the color filter layer 600 includes the first color filter 610′, the second color filter 620, and the third color filter 630. The filter layer 750 may be disposed on the entire surface of the color filter layer 600. When the light transmission spectrum of the first color filter 610′ of FIG. 15 is shifted toward a short wavelength, the first color filter 610′ may transmit some of green light and yellow light. The filter layer 750 may filter this yellow light. For example, the filter layer 750 may transmit light of about 530 nm to about 780 nm. The filter layer 750 may improve reflectivity of the display apparatus.

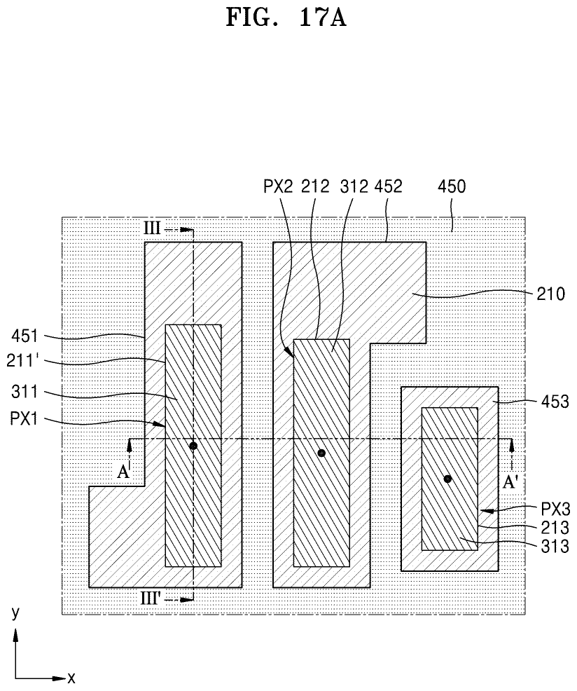

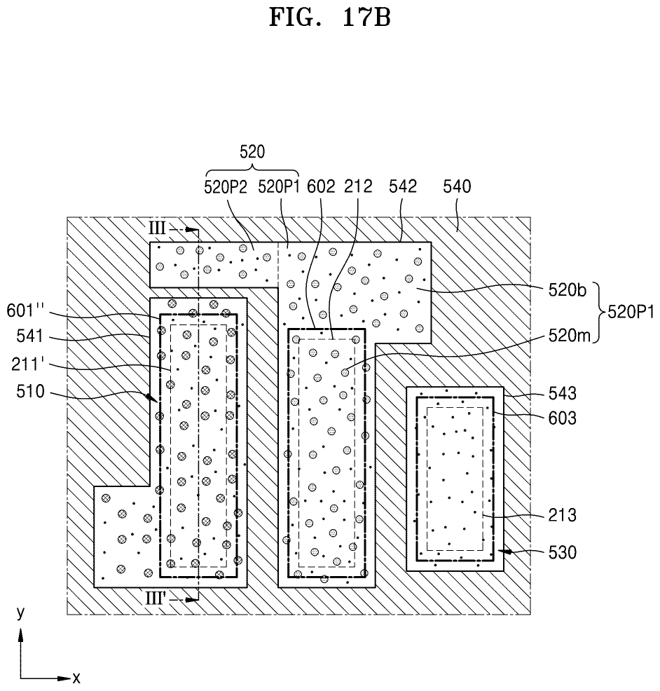

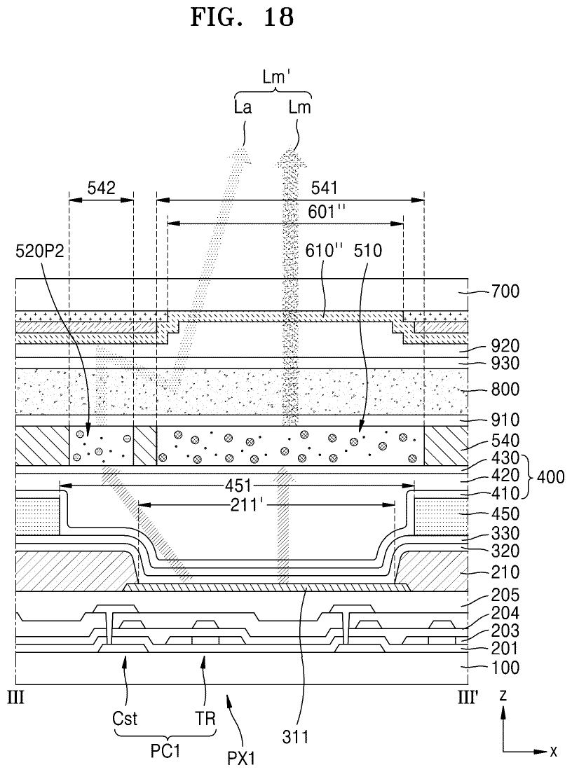

FIGS. 17A and 17B are plan views schematically illustrating a portion of a display apparatus according to an embodiment. FIGS. 17A shows a portion of the display apparatus, including the first to third sub-pixel electrodes 311, 312, and 313, the pixel-defining layer 210, and the first bank layer 450. FIG. 17B shows a portion of the display apparatus, including the second bank layer 540, the first quantum dot layer 510, the second quantum dot layer 520, and the light-transmitting layer 530. FIG. 18 is a cross-sectional view taken along line III-III′ of FIGS. 17A and 17B. FIGS. 17A, 17B, and 18 are modifications of FIGS. 8A, 8B, and 9, respectively, and differences are mainly described below.

Referring to FIGS. 17A and 17B, in an embodiment, the first quantum dot layer 510 may overlap the first sub-pixel opening 211 of the pixel-defining layer 210. The second portion 520P2 of the second quantum dot layer 520 may not overlap the first sub-pixel opening 211 of the pixel-defining layer 210. In other words, the first sub-pixel opening 211 of the pixel-defining layer 210 may overlap only the first quantum dot layer 510 and may not overlap the second quantum dot layer 520, for example, the second portion 520P2 of the second quantum dot layer 520. The first portion 520P1 of the second quantum dot layer 520 may overlap the second sub-pixel opening 212 defined in the pixel-defining layer 210. The light-transmitting layer 530 may overlap the third sub-pixel opening 213 defined in the pixel-defining layer 210 in a plan view.

The first quantum dot layer 510 may overlap the first-1 bank opening 451 defined in the first bank layer 450. The second portion 520P2 of the second quantum dot layer 520 may overlap the first-1 bank opening 451 defined in the first bank layer 450. In other words, the first-1 bank opening 451 defined in the first bank layer 450 may overlap the first quantum dot layer 510 and the second portion 520P2 of the second quantum dot layer 520. The first portion 520P1 of the second quantum dot layer 520 may overlap the first-2 bank opening 452 defined in the first bank layer 450. The light-transmitting layer 530 may overlap the first-3 bank opening 453 in a plan view.

Referring to FIGS. 17B and 18, the second color filter 620 may have the third filter opening 603 corresponding to the light-transmitting layer 530. The third filter opening 603 defined in the second color filter 620 may overlap the third sub-pixel opening 213 defined in the pixel-defining layer 210. The third filter opening 603 defined in the second color filter 620 may define an area of the third sub-pixel PX3.

In addition, the third color filter 630 may have the second filter opening 602 corresponding to the first portion 520P1 of the second quantum dot layer 520. The second filter opening 602 defined in the third color filter 630 may overlap the second sub-pixel opening 212 defined in the pixel-defining layer 210 in a plan view. The second filter opening 602 defined in the third color filter 630 may define the area of the second sub-pixel PX2.

Meanwhile, the third color filter 630 may have a first filter opening 601″ corresponding to the first quantum dot layer 510. In a plan view, the first filter opening 601″ may be arranged adjacent to the second portion 520P2 of the second quantum dot layer 520. The first filter opening 601″ defined in the third color filter 630 may overlap the first sub-pixel opening 211 defined in the pixel-defining layer 210 in a plan view. The first filter opening 601″ defined in the third color filter 630 may define the area of the first sub-pixel PX1.

The third color filter 630 may fill in the third filter opening 603 defined in the second color filter 620. The second color filter 620 may fill in the second filter opening 602 defined in the third color filter 630. A first color filter 610″ may fill in the first filter opening 601″ defined in the third color filter 630.

In an embodiment, the second portion 520P2 of the second quantum dot layer 520 may correspond to a light-shielding portion that the first color filter 610″, the second color filter 620, and the third color filter 630 overlap.

The first color filter 610″ of FIG. 18 may include a composition different from a composition of the first color filter 610 of FIG. 9. A light transmission spectrum of the first color filter 610″ of FIG. 18 may be shifted toward a shorter wavelength than the light transmission spectrum of the first color filter 610 of FIG. 9. For example, the first color filter 610″ may transmit light of about 530 nm to about 780 nm.

Referring to FIG. 18, in the area of the first sub-pixel PX1, light generated on the first sub-pixel opening 211′ of the pixel-defining layer 210 (e.g., light in the first wavelength band emitted from the first light-emitting element LED1, including blue light) may move within the first-1 bank opening 451 defined in the first bank layer 450 and may be incident on the first quantum dot layer 510. In addition, a high angle component (when direction of light component with respect to the normal direction (z-axis direction) of a x-y plane (major surface of the first sub-pixel electrode 311) forms an angle greater than a predetermined angle (e.g., 45 degrees)) of the light generated on the first sub-pixel opening 211′ may move within the first-1 bank opening 451 defined in the first bank layer 450 and may be incident on the second portion 520P2 of the second quantum dot layer 520. First red light Lm converted in the first quantum dot layer 510 and passing through the first color filter 610″ (e.g., light passing through the first color filter 610″ from among light in the second wavelength band that is converted in the first quantum dot layer 510) may be emitted from the area of the first sub-pixel PX1. Second green light La converted in the second portion 520P2 of the second quantum dot layer 520, reflected from the light-shielding portion, and passing through the first color filter 610″ (e.g., light passing through the first color filter 610″ from among light in the third wavelength band that is converted in the second portion 520P2 of the second quantum dot layer 520) may be emitted from an area of an adjacent first sub-pixel PX1. Light Lm′ emitted from the area of the first sub-pixel PX1 may be a mixture of the first red light Lm and the second green light La.

The first quantum dot layer 510 of the display apparatus 1 may be designed to emit red light with a high color gamut based on BT2020. However, according to an embodiment, without changing a material such as quantum dots of the first quantum dot layer 510, green light emitted from a portion of the second quantum dot layer 520 (e.g., the second portion 520P2 of the second quantum dot layer 520) may pass through a color filter under appropriate conditions and may be mixed with red light emitted from the first quantum dot layer 510 in the area of the first sub-pixel PX1, thereby improving a color gamut that is based on the DCI standard.

In an embodiment, the green light emitted from the second quantum dot layer 520 may have a wavelength band of a shorter wavelength than a wavelength band of green light to be mixed with the first red light Lm of the area of the first sub-pixel PX1, so as to improve the color gamut based on DCI.

The first color filter 610″ may transmit light in a wavelength band of a shorter wavelength than the first color filter 610 (see FIG. 9). The first color filter 610″ may transmit red light emitted from the first quantum dot layer 510 and some of green light emitted from the second portion 520P2 of the second quantum dot layer 520. The second green light La passing through the first color filter 610″ may correspond to light belonging to a wavelength band of a long wavelength from among the green light emitted from the second quantum dot layer 520.

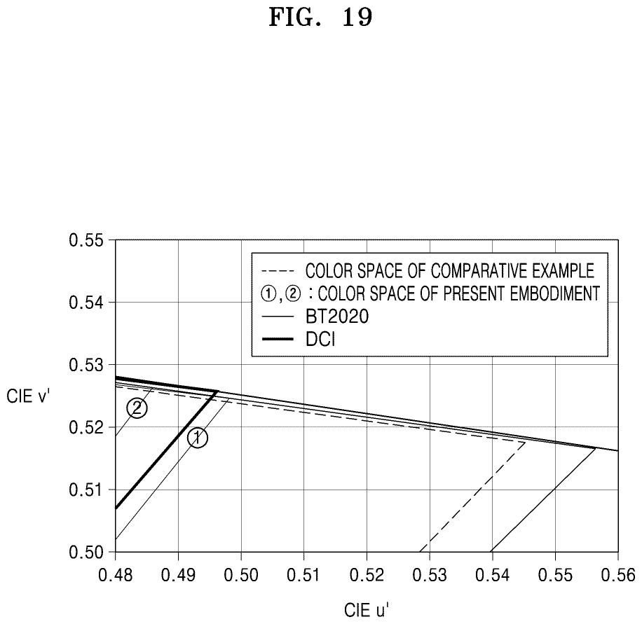

FIG. 19 is a graph schematically showing a color space of a display apparatus and a digital cinema initiatives (DCI) color space in which a red portion is enlarged, according to an embodiment. The DCI color space is indicated by a dark solid line, the BT2020 color space is indicated by a thin solid line, and a color space displayed in the display apparatus according to an embodiment is indicated by symbols \textcircled{1} and \textcircled{2}. In addition, a color space displayed in the display apparatus according to a comparative example is indicated by a dotted line.

Referring to FIG. 19, in the red portion, the BT2020 color space and the DCI color space may be different from each other. The closer the color space of the display apparatus is to the BT2020 color space, the higher the color gamut based on BR2020, while the color gamut based on DCI may decrease. The closer the color space of the display apparatus is to the DCI color space, the higher the color gamut based on DCI, while the color gamut based on BR2020 may decrease. In color coordinates in which the horizontal axis is u′ and the vertical axis is v′, the closer a value of u′ corresponding to red color of the color space of the display apparatus is to a value of u′ corresponding to red color in the DCI color space, the better the color gamut based on DCI can be obtained. The closer a value of v′ corresponding to red color of the color space of the display apparatus is to a value of v′ corresponding to red color in the DCI color space, the better the color gamut based on DCI can be obtained.

In the display apparatus according to the comparative example, only red light emitted from the first quantum dot layer may be emitted from the area of the first sub-pixel. The first quantum dot layer may be designed to emit light with a high color gamut based on BT2020.

However, in the display apparatus according to one or more embodiments, a portion of the second quantum dot layer 520 (e.g., the second portion 520P2 of the second quantum dot layer 520) corresponds to the area of the first sub-pixel PX1 or is arranged adjacent to the area of the first sub-pixel PX1, and green light emitted from this portion of the second quantum dot layer 520 (e.g., the second portion 520P2 of the second quantum dot layer 520) passes through a color filter under appropriate conditions and is mixed with red light emitted from the first quantum dot layer 510 in the area of the first sub-pixel PX1.

As shown in FIG. 19, the color space of the display apparatus according to one or more embodiments may be closer to the DCI color space than the color space of the display apparatus according to the comparative example. According to an embodiment, the color gamut based on DCI, of the display apparatus, may be improved without changing a material, such as quantum dots, of the first quantum dot layer 510.

According to one or more embodiments, a display apparatus with excellent color purity and excellent light efficiency may be provided. However, the scope of one or more embodiments is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a first substrate;
a first light-emitting element to a third light-emitting element disposed on the first substrate;
a sub-pixel-defining layer in which a first opening to a third opening are defined, the first opening to the third opening overlapping the first light-emitting element to the third light-emitting element, respectively, in a plan view;
an encapsulation layer disposed on the sub-pixel-defining layer and comprising at least one inorganic encapsulation layer and at least one organic encapsulation layer;
a functional layer disposed on the encapsulation layer, the functional layer comprising a first quantum dot layer corresponding to the first light-emitting element and a second quantum dot layer corresponding to the second light-emitting element; and
a color filter layer disposed in a direction of light output from the first light-emitting element to the third light-emitting element, the color filter layer comprising a first color filter corresponding to the first light-emitting element, a second color filter corresponding to the second light-emitting element, and a third color filter corresponding to the third light-emitting element,
wherein, in the plan view, the second quantum dot layer comprises a first portion overlapping the second opening, and a second portion, which extends from the first portion in a direction from the second opening to the first opening, and the second portion is adjacent to the first quantum dot layer.

2. The display apparatus of claim 1, further comprising a bank layer which is disposed between the sub-pixel-defining layer and the encapsulation layer and in which a first-1 bank opening to a first-3 bank opening overlapping the first light-emitting element to the third light-emitting element, respectively, in the plan view are defined,
wherein the bank layer comprises a light-shielding material, and
the second portion of the second quantum dot layer overlaps the first-1 bank opening in the plan view.

3. The display apparatus of claim 1, further comprising:
a second substrate arranged to face the first substrate;
a low-refractive layer arranged to cover the color filter layer, the color filter layer being disposed on a surface of the second substrate; and
a filler disposed between the low-refractive layer and the functional layer.

4. The display apparatus of claim 1, wherein the second portion of the second quantum dot layer overlaps the first opening in the plan view.

5. The display apparatus of claim 4, wherein the color filter layer further comprises a fourth color filter, which overlaps the second portion of the second quantum dot layer in the plan view,
the second color filter overlaps the first portion of the second quantum dot layer in the plan view, and
the fourth color filter comprises a composition different from a composition of the second color filter.

6. The display apparatus of claim 4, wherein the second color filter comprises a first filter portion overlapping the first portion of the second quantum dot layer and a second filter portion overlapping the second portion of the second quantum dot layer in the plan view,
the second filter portion comprises a same composition as the first filter portion, and
a thickness of the second filter portion is greater than a thickness of the first filter portion.

7. The display apparatus of claim 4, wherein the first color filter overlaps the second portion of the second quantum dot layer in the plan view.

8. The display apparatus of claim 7, further comprising a filter layer disposed entirely on the color filter layer.

9. The display apparatus of claim 1, wherein the second portion of the second quantum dot layer does not overlap the first opening in the plan view.

10. The display apparatus of claim 9, wherein at least two selected from the first color filter, the second color filter, and the third color filter overlap each other in a certain portion and the certain portion defines a light-shielding portion, and
the second portion of the second quantum dot layer overlaps the light-shielding portion in the plan view.

11. The display apparatus of claim 1, wherein the first light-emitting element to the third light-emitting element comprise an emission layer of a first color and an emission layer of a second color.

12. A display apparatus comprising:
a first substrate;
a first light-emitting element to a third light-emitting element disposed on the first substrate;
a sub-pixel-defining layer in which a first opening to a third opening are defined, the first opening to the third opening overlapping the first light-emitting element to the third light-emitting element, respectively, in a plan view;
a bank layer which is disposed on the sub-pixel-defining layer and in which a first-1 bank opening to a first-3 bank opening overlapping the first light-emitting element to the third light-emitting element, respectively, in the plan view are defined;
an encapsulation layer disposed on the bank layer and comprising at least one inorganic encapsulation layer and at least one organic encapsulation layer;
a functional layer disposed on the encapsulation layer, the functional layer comprising a first quantum dot layer corresponding to the first light-emitting element and a second quantum dot layer corresponding to the second light-emitting element; and
a color filter layer disposed in a direction of light output from the first light-emitting element to the third light-emitting element, the color filter layer comprising a first color filter corresponding to the first light-emitting element, a second color filter corresponding to the second light-emitting element, and a third color filter corresponding to the third light-emitting element,
wherein the second quantum dot layer overlaps the first-1 bank opening in the plan view.

13. The display apparatus of claim 12, wherein the bank layer comprises a light-shielding material.

14. The display apparatus of claim 12, wherein, in the plan view, the second quantum dot layer comprises a first portion overlapping the second opening, and a second portion, which extends from the first portion in a direction from the second opening to the first opening, and the second portion is adjacent to the first quantum dot layer.

15. The display apparatus of claim 14, wherein the second portion of the second quantum dot layer overlaps the first opening in the plan view.

16. The display apparatus of claim 15, wherein the color filter layer further comprises a fourth color filter, which overlaps the second portion of the second quantum dot layer in the plan view,
the second color filter overlaps the first portion of the second quantum dot layer in the plan view, and
the fourth color filter comprises a composition different from a composition of the second color filter.

17. The display apparatus of claim 15, wherein the second color filter comprises a first filter portion overlapping the first portion of the second quantum dot layer and a second filter portion overlapping the second portion of the second quantum dot layer in the plan view,
the second filter portion comprises a same composition as the first filter portion, and
a thickness of the second filter portion is greater than a thickness of the first filter portion.

18. The display apparatus of claim 15, wherein the first color filter overlaps the second portion of the second quantum dot layer in the plan view.

19. The display apparatus of claim 14, wherein the second portion of the second quantum dot layer does not overlap the first opening in the plan view.

20. The display apparatus of claim 19, wherein at least two selected from the first color filter, the second color filter, and the third color filter overlap each other in a certain portion and the certain portion defines a light-shielding portion, and
the second portion of the second quantum dot layer overlaps the light-shielding portion in the plan view.
